(19) United States
(12) Patent Application Publication
(10) Pub. No.: US 2025/0209226 A1
(43) Pub. Date: Jun. 26, 2025

(54) ARTIFICIAL INTELLIGENCE BASED DATA EXTRACTION FOR USER-DEFINED DESIGN PLAN SEGMENTATION

(71) Applicant: Togal.AI Inc., Miami, FL (US)

(72) Inventors: Patrick E. Murphy, Miami, FL (US); Johnny Maghzal, Miami, FL (US)

(73) Assignee: Togal.AI Inc., Miami, FL (US)

(21) Appl. No.: 18/990,710

(22) Filed: Dec. 20, 2024

Related U.S. Application Data
(60) Provisional application No. 63/613,692, filed on Dec. 21, 2023.

(51) Int. Cl. G06F 30/13

(52) U.S. Cl. CPC G06F 30/13

(57) ABSTRACT

Methods and systems employing artificial intelligence for efficient data extraction and analysis for a user-defined design plan segmentation. The method enables users to select specific segments within two-dimensional design plans, thereby triggering an AI engine to execute pixel-pattern analysis on the chosen segments. This process facilitates the extraction of comprehensive data related to these segments, encompassing detailed segment-specific information, aggregated counts of similar segments in the design plans, material lists, material costs, and labor expenses. Additionally, the invention includes methods for component searching within the design plans using symbols or polygon shapes selected by users, involving pixel-level analysis to identify matching dynamic components within the design plans. The resulting comprehensive data involves specific component details, quantities, associated costs, and possible automated suggestions for design alterations, enhancing user decision-making and enabling seamless planning aligned with users' budget and quality standards.

### FIELD OF THE INVENTION

This application claims the benefit of U.S. Provisional Patent Application No. 63/613,692, filed Dec. 21, 2023, and entitled ARTIFICIAL INTELLIGENCE BASED DATA EXTRACTION FOR USER-DEFINED DESIGN PLAN SEGMENTATION, the entire disclosure of which is incorporated herein by reference.

### FIELD OF THE INVENTION

The present invention provides improved system, methods and apparatus employing artificial intelligence for efficient data extraction and analysis for a user-defined design plan segmentation. More specifically, the present invention provides for system and methods that analyze two-dimensional design plans and allows users to select specific portions, segments, or regions of the design plans, triggering an Artificial Intelligence (AI) engine to perform pixel and/or polygon analysis on the selected portions, segments, or regions, thereby extracting comprehensive data related to the chosen segment. The extracted information encompasses segment-specific details, the aggregate count of similar segments within the design plans, associated material lists, material costs, labor costs for building and/or installing individual or multiple such segments, facilitating streamlined planning and cost estimation.

### BACKGROUND OF THE INVENTION

Traditionally, the process of extracting comprehensive data from design plans, particularly in construction and architectural domains, has been labor-intensive and prone to errors. Conventional methods often necessitate manual examination and interpretation of design blueprints, leading to time-consuming efforts and inaccuracies in material estimation and cost projections. The human-driven nature of these methods made them susceptible to inconsistencies and discrepancies, impacting the precision of project planning and execution.

Existing computer-aided design (CAD) software tools, aimed to streamline these processes through automation, their effectiveness remained limited. While providing a degree of automation, these tools lacked the required granularity and precision necessary for conducting detailed segment-specific analysis and accurate cost estimations. The inherent limitations of these software tools became evident when confronted with the intricacies of design plan segmentation and the need for precise data extraction.

In attempts to address these limitations, considerable efforts have been invested in automating aspects of design plan analysis using computer algorithms. However, these endeavors fell short in delivering comprehensive data extraction and analysis at a granular level, particularly in the context of user-defined segmentation within design plans. Existing algorithmic approaches, though promising, failed to provide the depth of detailed information essential for precise segment-specific analysis and comprehensive cost estimation.

The shortcomings of traditional methodologies and existing tools underscore a significant gap between the capabilities of current systems and the demands of the industry. The complexity of design plans, coupled with the need for accurate data extraction and precise cost estimation, remains a challenge.

### SUMMARY OF THE DISCLOSURE

Recognizing the above limitations, the present invention emerges as a breakthrough solution aimed at revolutionizing design plan analysis by harnessing the power of cutting-edge technologies, specifically artificial intelligence (AI). By empowering users to precisely select segments within two-dimensional design plans, this invention triggers an AI-driven process that conducts meticulous pixel-level analysis of the designated areas. This AI-powered engine enables the extraction of comprehensive data related to the selected segments, encompassing detailed segment-specific specifications, counts of similar segments across the design plans, associated material lists, material costs, and labor costs for construction and installation.

The present invention overcomes the limitations of existing methods by introducing an innovative system and method that use artificial intelligence for design plan analysis. This invention empowers users to precisely select segments, elements or components within two-dimensional design plans and triggers an AI-driven process that conducts pixel-level analysis of the chosen area. The AI engine efficiently extracts comprehensive data related to the selected segment, including segment-specific details, counts of similar segments within the design plans, associated material lists, material costs, and labor costs for construction and installation. Such detailed information allows for streamlined planning, accurate cost estimation, and facilitates informed decision-making in design and construction projects.

Accordingly, the present disclosure provides methods and apparatus for architects, owners, developers, engineers, compliance reviewers, builders, and other users to analyze two-dimensional (sometimes referred to herein as “2D”) references, such as floorplans, design plans, blueprints, and the like, with the aid of artificial intelligence (sometimes referred to herein as “AI” and an AI platform programmed to accomplish the methods described herein as an “AI Engine”), these tools empower users to select specific segments, elements or components within the designs, thereby discerning the specific types of elements present within the design plans based on a meticulous pixel-level examination by the AI engine. These elements encompass a diverse array including but not limited to: walls, windows, doors, stairwells, staircases, ramps, ceilings, floors, columns, beams, roof, skylights, facades, and an assortment of other architectural components. Furthermore, the present system excels in extracting comprehensive data associated with these identified elements. This data spans a broad spectrum, incorporating, but not limited to, the quantity of such elements represented in the design plans, the estimated costs linked to constructing or installing these elements, and even AI-generated recommendations aimed at enhancing the comfort, aesthetics, and overall appearance of these architectural facets.

In general, the present invention provides for apparatus and methods related to receiving as input two-dimensional representations (either physical or electronic) and generating one or more pixel patterns based upon automated processing of the two-dimensional representations. The pixel patterns are analyzed using computerized processing techniques to mimic the perception, learning, problem-solving, and decision-making formerly performed by human workers (sometimes referred to herein as artificial intelligence or “AI”). The AI analysis process is repeated for multiple two-dimensional representations over time, each two-dimensional representation including a change to a design of a building be constructed. The AI processes denote, and track changes made in the sequence of two-dimensional representations of design documents.

Based upon AI analysis of pixel patterns derived from the two-dimensional references and knowledge accumulated from increasing volumes of analyzed two-dimensional references, interactive user interfaces may be generated that allow for a user to modify dynamic two-dimensional representations of features gleaned from the two-dimensional reference. The interactive user interfaces may enable users to select specific portions or segments on the design plans, wherein the AI engine employs AI processing to determine the elements or components present within the chosen segment by analyzing the pixel patterns of the two-dimensional references. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from previous work, whether or not a human was involved, hence the importance of integrating our AI with existing databases.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind including learning from examples and experience, recognizing patterns and/or objects, understanding and responding to patterns in positions relative to other patterns, making decisions, solving problems. The analysis also combines these and other capabilities to perform functions the skilled labor force traditionally performed.

The methods and apparatus of the present invention are presented herein generally, by way of example, to actions, processes, and deliverables important to industries such as the construction industry, by providing comprehensive data related to the components identified in the selected segments of the two-dimensional references that include blueprints, design plans, floor plans or other construction related diagrams, however, two-dimensional references may include almost any two-dimensional artifact that may be converted to a pixel pattern.

In some specific examples, the present invention uses machine learning and/or artificial intelligence to identify architectural aspects and materials, such as walls, stairwells, floors, ceilings, doors, windows, and HVAC components, within the selected portion of the design plan. The present invention identifies such architectural aspects and other building features and provides comprehensive data related to such components including some system provided automated suggestions. The comprehensive data related to such components may include but not limited to: name and/or type of components, number of such components within the design plan, and cost associated with building or installing such components. The automated suggestions may include a wide range of recommendations but not limited to: proposed design alterations, dimension adjustments, length and width suggestions, material specifications including recommended brands for the components, compliance adherence advice, safety enhancements, and a plethora of other pertinent insights aimed at optimizing the design and construction process.

In some preferred embodiments, the AI Engine is seamlessly integrated with databases housing a repository of past similar projects. These databases serve as helpful resources, facilitating the AI engine's learning process by drawing insights from diverse user decisions made in comparable prior works. This integration empowers the AI Engine with a wealth of accumulated knowledge, enhancing its ability to offer informed and contextually relevant recommendations.

Furthermore, according to some embodiments of the present invention, the system can be integrated with advertisement platforms which deliver advertisements to users on the interactive user interfaces. The advertisement may comprise but not limited to: components from particular brands that align with both the required quality standards and the user's budget, alternative components from diverse brands, comprehensive lists of materials complete with pricing and purchase options, and even contact information or details of contractors and architects available for hire, specializing in the realization of the actual building based on the design plan.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, dead ends, windows, or other discrete aspects of a building.

A scaling process is applied to the floorplan and size descriptors are assigned to the discernable components. In addition, distances, such as, for example, a distance to an exit from the furthest point in a residential unit are calculated.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (such computerized processing techniques are sometimes referred to herein as artificial intelligence or “AI” processing or analysis).

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional references.

In specific embodiments of the invention, the method involves several key processes: receiving two-dimensional representations of a design plan as input into a controller housing the AI engine; generating pixel patterns through automated processing of these representations; analyzing multiple two-dimensional representations over time using the AI engine; representing the design plan (or a portion of it) as a raster image; utilizing the AI engine on the controller to analyze the raster image, identifying components depicted in the design plan; determining the scale of these components; constructing a user interface featuring various components, arranging them to establish boundaries; generating features' areas or lengths based on these boundaries; enabling user selection of a segment within the design plan via the user interface; leveraging the AI engine to identify the component(s) within the chosen segment, employing AI analysis of the segment's polygons; and finally, displaying comprehensive data related to the identified component(s) on the user interface. Furthermore, alternative embodiments may comprise computer systems, apparatus, and computer programs stored on one or more computer storage devices. Each configuration is tailored to execute the aforementioned methods and functionalities.

In specific embodiments of the invention, the process of selecting a segment may involve one or both of the following actions: marking around or on the desired segment directly within the user interface or utilizing a polygon shape tool accessible on the interface, enabling users to drag and position the shape onto the desired segment. Moreover, the selection of a segment can be initiated either manually by a user or automatically by the AI engine. Additionally, when employing the polygon shape tool, users may choose from a range of polygon shapes provided by the AI engine within the user interface for selection and placement.

In specific embodiments of the invention, the AI engine analyzes the selected segment based on pixel-level analysis of the selected segment area within the design plan covered by the user-provided marking or the selected polygon shape. The pixel-level analysis may comprise considering the pixels of the two-dimensional representation for analysis if the pixels are at and/or around a tolerable distance from the marking or boundaries of the polygon shape. The pixel-level analysis may comprise analyzing the polygon pixel patterns of the segment covered by the selected polygon shape. The pixel-level analysis may further comprise considering the pixels of the two-dimensional representation for analysis if the pixels are at a predefined distance from each other creating a particular spatial relationship. The spatial relationship may be defined by a user or automatically learned by the AI engine.

In specific embodiments of the invention, the system provides users with a user interface offering the capability to search for a segment within the two-dimensional representation of the design plan based on a symbol or polygon shape chosen or entered by the users. The symbols or polygon shapes that users may select, or input encompass a diverse range of architectural components including but not limited to: a door, a window, a stairwell, a wall, floors, ceilings, ramps, columns, beams, roof, skylights, facades and HVAC components. This intuitive interface enables efficient and targeted identification of specific elements within the design plan based on selected symbols or polygon shapes.

In specific embodiments of the invention, the method involves receiving into a controller a two-dimensional representation of at least a portion of the building; analyzing a first raster image representing the two-dimensional representation with an AI engine operative on the controller to ascertain multiple components in the two-dimensional representation and represented as a pattern of pixels in the raster image; generating an interactive user interface comprising multiple vertices including one or both of dynamic lines and dynamic polygons to represent at least some of the multiple components included in the two-dimensional representation as dynamic components descriptive of architectural aspects in the interactive user interface; receiving into the controller a symbol or polygon shape selected by the user as a search query; analyzing the symbol or polygon shape at pixel-level and comparing with the multiple components included in the two-dimensional representation; generating at least one match based on the comparison; providing a list of components included in the two-dimensional representation having a match with the symbol or polygon shape; and displaying on the user interface a comprehensive data related to the matched components included in the two-dimensional representation.

In some embodiments of the invention, the method may involve receiving, into a controller, a two-dimensional representation of a design plan of at least a portion of the building. Representing at least a portion of the design plan as multiple dynamic components, the method generates an interactive user interface comprising at least some of these dynamic components, each with a changeable parameter via the interface. As a search query, the controller receives the user-selected symbol, analyzing it at pixel-level and comparing it with the multiple dynamic components representing the design plan. Based on this comparison, at least one match of a dynamic component corresponding to the user-selected symbol is generated. The method provides a list of these matching dynamic components, extracts comprehensive data related to them, and displays this comprehensive data on the interactive user interface.

Building upon the method previously described, the comprehensive data extracted from the identified dynamic components may include helpful details such as component names, types, quantities, and associated costs. Expanding on this, the method may introduce automated suggestions tailored to the matched dynamic components. These suggestions may cover proposed design alterations, dimension adjustments, length and width recommendations, material specifications from preferred brands, compliance adherence advice, and safety enhancement recommendations.

Regarding the symbols used as queries, they may encompass a broad spectrum from polygon shapes to specific architectural elements like doors, windows, stairwells, walls, floors, ceilings, ramps, columns, beams, roofs, skylights, facades, and HVAC components. Additionally, the method may extend to displaying advertisements on the interactive user interface. These advertisements may comprise dynamic components from specific brands or alternative brands that align with the user's quality standards and budget. The advertisements may also include comprehensive lists of materials with pricing and purchasing options, along with contact details for available contractors and architects for hire. The user's quality standards and budget may be specified by the user through the interactive user interface.

Moreover, in-depth pixel-level analysis may involve considering spatial relationships between pixels within the two-dimensional representation, ensuring a predefined distance between them, thus refining the precision of the analysis process.

In some embodiments of the invention, a method for extracting comprehensive data related to a dynamic component included in a two-dimensional representation of a design plan may encompass the following steps. Initially, the controller may receive the two-dimensional representation of the design plan and segment it into multiple dynamic components, each adjustable via the interactive user interface. Subsequently, a user may select a segment of the design plan on the interface, initiating a pixel-level analysis by the AI engine on the controller. This analysis may further compare the selected segment with the dynamic components representing the design plan, generating at least one match corresponding to the selected segment. Following this comparison, the method presents a list of matching dynamic components, extracts comprehensive data associated with these matched components, and seamlessly displays this comprehensive data on the interactive user interface for the user's perusal.

In some embodiments of the invention, the method may comprise the segment selection process within the design plan. Users have the flexibility to mark on or around desired segments directly within the interactive interface or employ a polygon shape tool accessible on the interface, allowing the positioning of various polygon shapes onto desired segments. This tool offers a selection of polygon shapes sourced from the AI engine, enhancing precision in segment placement. Furthermore, the method intricately examines the pixel patterns within the selected segments covered by chosen polygon shapes, ensuring a predefined spatial relationship between pixels to enrich the analysis. The comprehensive data extracted may include details such as component names, types, quantities, and associated costs related to the selected segment's dynamic components. Additionally, automated suggestions may comprise proposed design alterations, dimension adjustments, length and width suggestions, material specifications including recommended brands, compliance adherence advice, and safety enhancement advice. The segments within the design plan may comprise one or more of: polygon shapes and specific architectural components like doors, windows, stairwells, walls, floors, ceilings, ramps, columns, beams, roofs, skylights, facades, and HVAC elements. Moreover, the advertisements displayed on the interface may comprise dynamic components from a plurality of brands or manufacturers tailored to user quality standards and budget, alongside material lists with pricing and purchase options and contacts for contractors and architects available for hire.

In some embodiments, the two-dimensional reference input may be files extensions that include but are not limited to: DWG, DXF, PDF, TIFF, PNG, JPEG, GIF, or other type of file based upon a set of engineering drawings. Some two-dimensional reference references may already be in a pixel format, such as, by way of non-limiting example, a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. As some architects, design firms and others who generate engineering designs for buildings may be reluctant to share raw CAD files with others, the present invention provides a solution that does not require raw CAD files.

In other examples, such as for older structures, a drawing or other 2D representation may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or In some embodiments, via an application running on a smart device. In some embodiments, a user may operate a scanner or a smart device with a camera to create the file containing the image on the smart device.

In some embodiments, a system utilizes pixel patterns and polygon patterns in sizing analysis of the selected segments of design plans. The system incorporates a user-adjustable and/or AI-adjustable feature for sizing variations, utilizing percentage variation in pixel positions relative to other pixel positions within a defined window of the segment selection. It may involve convolutional filters for zero-shot and one-shot approaches, leveraging generative models and template matching. Another embodiment may incorporate relative positioning of pixels, employing mathematical representations, algorithms, and vector-based approaches for analyzing distances, angles, and clustering vectors into symbols. The system aims for optimization based on speed, quality, cost-effectiveness, durability, aesthetics, financial criteria, supply chain, labor costs, subcontractor selection, scope of work, location, equipment, spatial relevance, clearance, covering area, floor, ceiling, paths, plumbing, gas/chemical lines, cables, electrical wiring, and rule-based criteria. Users can select measurements such as length, area, volume, atmospheric volume, and relative height, further refining the system's analysis. This versatile approach prioritizes user-defined preferences and customizable variables to streamline decision-making and planning.

A primary advantage of AI analysis in this scenario is its capacity to analyze complex pixel patterns, vectors, and polygons using knowledge derived from previous experiences. This knowledge is not confined to the work of a single individual but can be harnessed from a select group of experts or shared learnings from similar past projects. This means that the AI system has access to a vast pool of information and insights, enabling it to make informed and effective decisions. Furthermore, the speed at which AI analysis can derive new and improved work based on the current design plan is a remarkable asset. It outpaces human processing capabilities, making the AI Engine a valuable tool for generating innovative solutions and optimizing design plans to extract comprehensive data related to desired segments and sustainable construction projects.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind—including learning from examples and experience, recognizing patterns and/or objects, understanding and responding to patterns in positions relative to other patterns, making decisions, solving problems. The analysis also combines these and other capabilities to perform functions the skilled labor force traditionally performed.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary method for selecting a desired segment of a design plan based on markings on or around a desired segment.

FIG. 1D illustrates an exemplary method for selecting a desired segment utilizing a plurality of polygon shapes.

FIGS. 1E and 1F illustrate exemplary displays on the interactive user interface showing comprehensive data related to matched dynamic components of the design plan.

FIGS. 2A, 2B, 2C and 2D illustrate a-two-dimensional representation of a floor plan and an AI analysis of same to assess boundaries.

FIGS. 3A-3D show various views of the AI-analyzed boundaries overlaid on the original floorplan including a table illustrated to contain hierarchical dominance relationships between area types.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols and an exemplary method for selecting a desired segment of the design plan.

FIG. 8 illustrates exemplary processor architecture for use with the present disclosure.

FIG. 9 illustrates exemplary mobile device architecture for use with the present disclosure.

FIGS. 10A-10B illustrate additional method steps that may be executed in some embodiments of the present invention.

FIG. 11 illustrates additional method steps that may be executed in some embodiments of the present invention.

### DETAILED DESCRIPTION

The present invention provides improved methods and apparatus for artificial intelligence-based conversion of a two-dimensional reference, such as a design plan, into an interactive interface for one or both of: extracting comprehensive data related to a dynamic component included in a two-dimensional representation of a design plan and searching components included in a two-dimensional representation of a design plan of a building based on a symbol or polygon shape.

According to the present invention, an AI Engine is deployed to scan a relevant design plan and quantify whether the design plan (or a selected segment/portion of the design plan) meets criteria for certification, local government requirements, produces documentation and evidence of compliance with various sustainability measures; produce documentation relating to requirement for compliance with local building codes and regulations that also meet green building requirements; provision and documentation of data and analysis that demonstrates various alternatives to reduce carbon emissions; extensive interdisciplinary collaboration among architects, engineers, contractors, and various stakeholders to ensure each part of the project aligns with various building requirements. This may also include verification of a desired segment of the design plan selected by a user as a search query. The desired segment may be selected for analysis based on one or both of: marking on or around a desired segment and selecting the desired segment utilizing a polygon shape tool accessible on the interactive user interface to drag and position a polygon shape onto the desired segment.

The present invention includes methods and apparatus to analyze a building (or other structure) design based upon automated AI analysis of a two-dimensional reference and applying machine learning to determine comprehensive data related to a desired or selected segment of the design plan as described in various embodiments of the invention.

The present invention utilizes an AI Engine with deep learning architectures, such as neural and adversarial networks, coupled with techniques including forward and reverse propagation. A unique user interactive interface includes editable lines, vectors, and polygons, which are leveraged by users to generate diagrams in real-time, creating improved sustainability analysis documents from two-dimensional references like blueprints or architectural drawings. The AI Engine also works for two-dimensional artifacts that can be converted into pixel patterns (e.g., walls, doorways, doors, plumbing, plumbing fixtures, hardware, fasteners, etc.), and values for variables can be defined through both AI and human input. The two-dimensional references, may be represented as images, identifying components (may be based on a search query or a making on the design plan), determining their scale, and generating user interfaces to calculate quantities of items needed for construction.

The apparatus and methods disclosed herein are capable of analyzing and allowing a user to understand content of two-dimensional references by identifying pixel patterns, and subsequently transforming them into two-dimensional representations or actionable data. An interactive user interface is created that empowers users to modify and interact with the two-dimensional representations dynamically.

The interactive interface is operative to generate values of variables useful to ascertain whether the submitted design plan meets or exceeds a designated building code pertaining to a geographic and/or geopolitical area. The interactive interface may also include specific requirements of a building code and indications of whether some or all of the requirements are met. In addition, the interface may include pictorial indications of portions of a design plan that have been associated with specific requirements of the building code during the AI analysis. The pictorial indications may include description of why a particular portion meets, exceeds, or does not meet a compliance code requirement. The interactive interface may allow a user to select a portion or segment of the design plan to determine compliance requirements associated with the selected portion besides extracting a detailed information related to the selected portion.

As described herein, a design plan may be associated with an existing building or a proposed project that includes construction of a building (or other structure, herein collectively referred to as a “building”). Generation of documentation quantifying compliance or non-compliance of a design plan or a selected segment with specific building codes is also within the scope of the present invention. In some embodiments, automated suggested revisions to the design plan to bring the design plan or the selected segment into conformity with the code are also within the scope of the invention. This innovative feature aims to assist designers and architects in aligning their design plans with building codes, ultimately enhancing the efficiency of the design and construction process. These automated suggestions for revisions to the design plan represent a dynamic and adaptive approach to ensure that the final design complies with the required standards, underscoring the adaptability and intelligence of the invention. Users can choose automated designs compliant with codes or make personalized modifications. Subsequent compliance analysis is then conducted based on user-altered designs, allowing flexibility and customization in the design process.

According to the present invention, a controller is operative to execute artificial intelligence (AI) processes and analyze one or more design plans of at least a portion of a building (or other structure) for which a comprehensive data will be generated.

In some embodiments, the design plan may include technical drawings such as blueprints, floor plans, design plans and the like. The AI analysis may include determination of boundaries and/or features indicated in the design plan. The design plan may be a two-dimensional static reference, or a two-dimensional or three-dimensional dynamic reference, such as, but not limited to, a Revit compatible file. This boundary determination may be used to provide useful information about a building such as, one or more of: rooms that comprise a residential unit; an area of an individual room or other area; a distance of travel to a point of egress, a width of a doorway; a width of a path or egress; a dead end path; a perimeter of a defined area; a point furthest from another point (e.g.; a point furthest from a point of egress); a common path; and the like. Based upon values of parameters derived from a two-dimensional reference, the AI engine may automatically generate comprehensive data related to all the components with a design plan.

In some embodiments, the present invention may analyze a two-dimensional reference and generate one or both of compliant paths from a defined room or a user-selected point in the design plan to a point of egress (or to another user-selected point in the design plan) and may provide automated suggestions related to the selected points on the design plan.

In some embodiments, the present invention may empower users with a dynamic exploration of the architectural blueprint. Through the interactive user interface, users can navigate and search for specific elements using symbols or polygon shapes, effectively querying the system to identify components matching the symbols or polygon shapes within the design plan. This intuitive approach enhances user engagement and efficiency, allowing for targeted searches and immediate access to comprehensive data regarding the matched components. Ultimately, this interactive and analytical framework streamlines the exploration and understanding of intricate building designs, enabling informed decision-making and precise identification of elements crucial to the construction process.

Some preferred embodiments include the utilization of the advanced AI engine to rigorously assess design plans for various types of buildings, such as schools, colleges, hospitals, malls, and structures with distinct safety prerequisites, especially in scenarios involving fires or seismic events (e.g., earthquakes). This innovative system may be used to ensure that these design plans align carefully with the stringent building codes and regulations specific to these categories of structures. These encompass a wide spectrum, covering crucial aspects like fire safety, earthquake resilience, accessibility, structural integrity, and ventilation systems, among others. The AI engine's primary function may be to determine the values associated with the variables within the design plan or within a selected portion in the design plan, meticulously verifying whether they meet the exacting requirements stipulated by the relevant building codes.

AI generated values for parameters may also be useful in a variety of estimation elements, such as (without limitation): flooring (wood, ceramic, carpet, tile, etc.), structural (poured concrete, steel), walls (gypsum, masonry blocks, glass walls, wall base, exterior cladding), doors and frames (hollow metal, wood, glass), windows glazing, insulation, paint (ceilings and walls), acoustical ceilings, code compliance, stucco (ceilings and walls), mechanical, plumbing, and electrical aspects. The estimation elements may be used to calculate a cost of construction to implement a modification to a building design or a selected portion of the building design in order to become compliant with a building code. The cost may be calculated based upon AI determination of architectural aspects, such as doorways, windows, angles in walls, curves in walls, plumbing fixtures, piping, wiring, electrical equipment, or boxes; duct work; HVAC fixtures and/or equipment; or other component or aspect included in an estimate for work to cause a building to be compliant.

In the following sections, detailed descriptions of examples and methods will be given. The description of both preferred and alternative examples, though thorough, are exemplary only. It is understood by those skilled in the art, that various modifications and alterations may be apparent and within the scope of the present invention. Unless otherwise indicated by the language of the claims, the examples do not limit the broadness of the aspects of the underlying invention as defined by the claims.

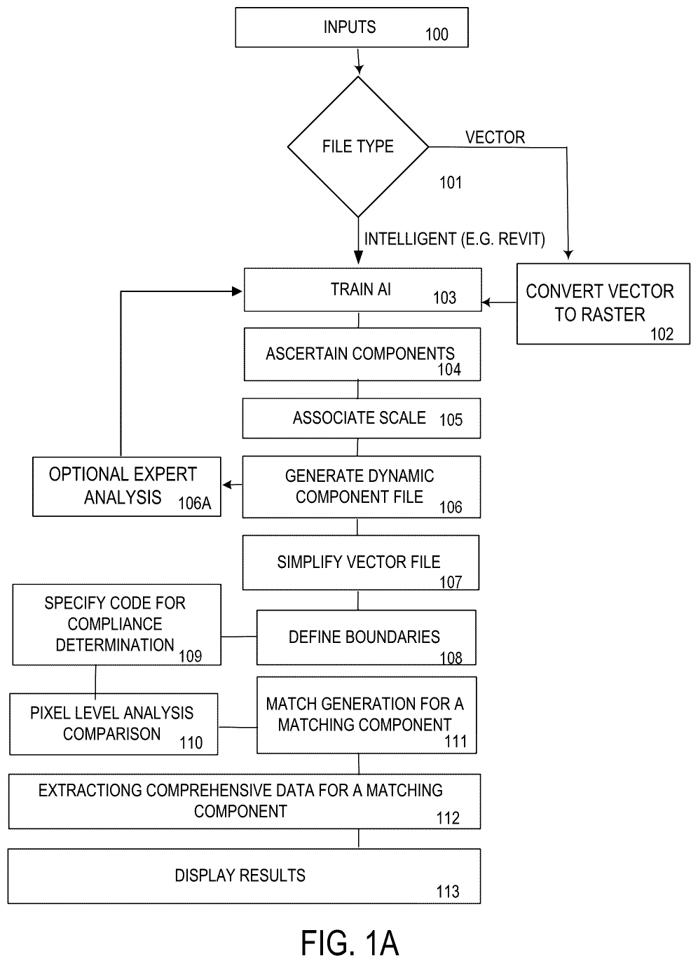

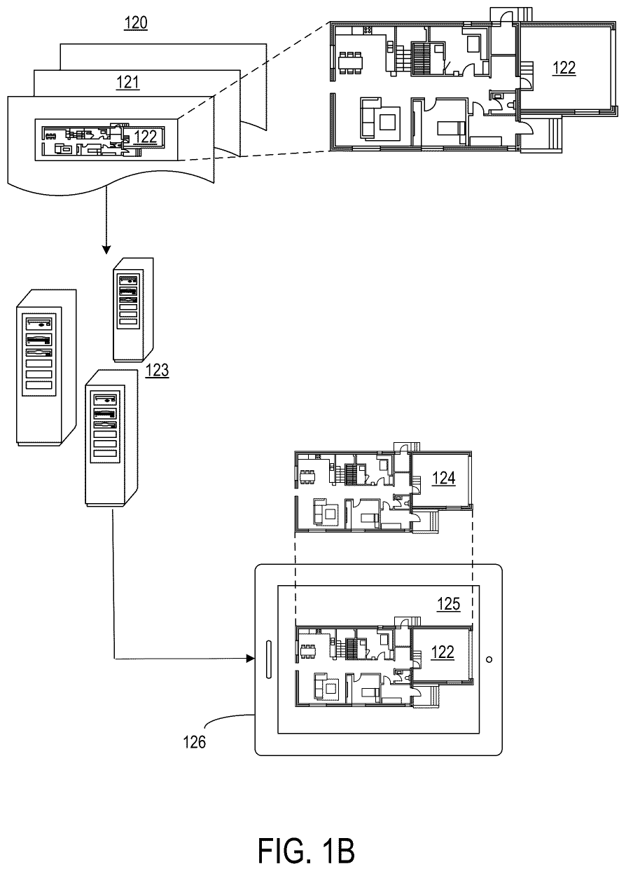

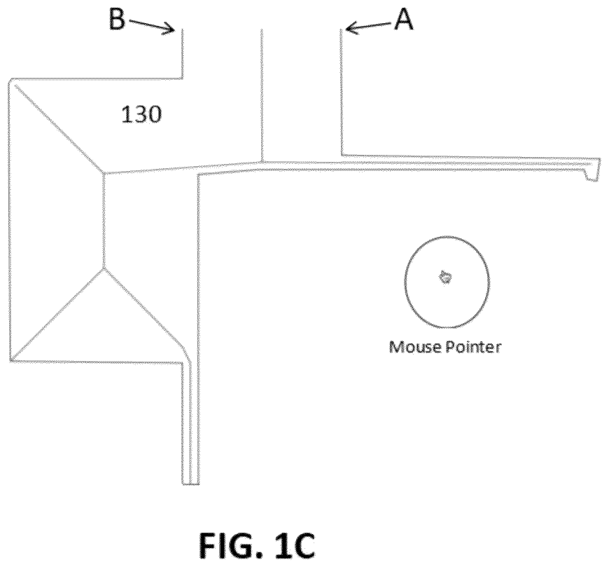

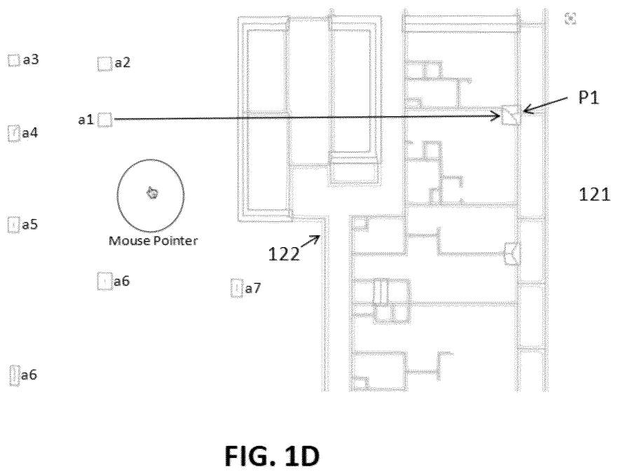

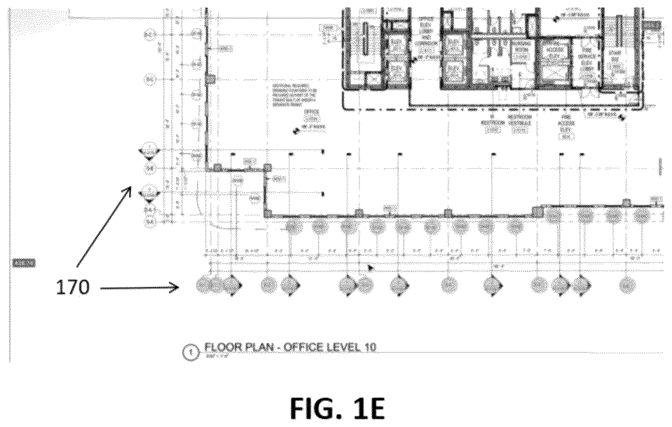

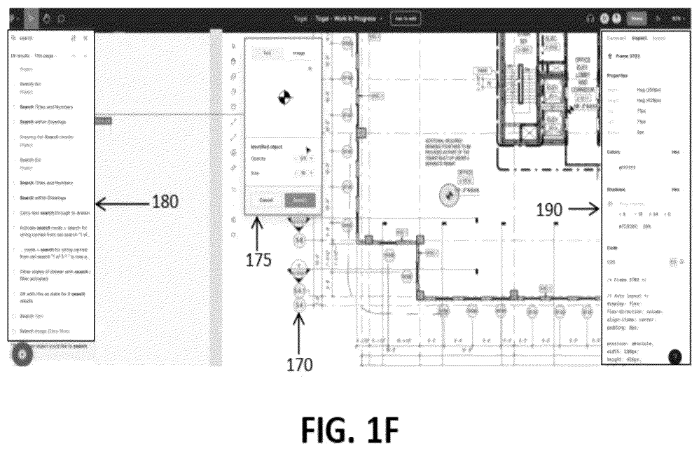

Referring now to FIG. 1A, a general flow diagram showing some preferred embodiments of the present invention as illustrated. At step 100, a design plan (which may be design plan or dynamic architectural design file e.g., a Revit® compatible file) indicating aspects of a building; is input into a controller or other data processing system using a computing device. The design plan may include an item of a known size, such as, by way of non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of a two-dimensional reference (i.e., design plan) into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be drawing file in an electronic file containing a model output for an architectural floor plan. In still further examples, other types of images stored in electronic files such as those generated by cameras may be used as inputs for automated processes.

In some embodiments, the design plan may be files extensions that include but are not limited to: DWG, DXF, PDF, TIFF, PNG, JPEG, GIF, or other type of file based upon a set of engineering drawings. Some design plans may already be in a pixel format, such as, by way of non-limiting example a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged couple device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied to a remote server. In some embodiments, the remote server, which is preferably a cloud server, may have significant computing resources that may be applied to AI algorithmic calculations analyzing the image.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments.

At step 101, the controller may determine if the design plan received into the controller includes a vector diagram. If a file type of the received design plan, such as an input architectural floor plan technical drawing, includes at least a portion that is not already in raster graphics image format (for example that it is in vector format), then the input architectural floor plan technical drawing may be transformed to a pixel or raster graphics image format in step 102. Vector-to-image transforming software may be executed by the controller, or via a specialized processor and associated software.

In some embodiments, the controller may determine a pixel count of a resulting rasterized file. The rasterized file will be rendered suitable for the controller hosting an artificial intelligence engine (“AI engine”) to process, the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet. As an illustrative example, images can be resized to dimensions such as 1024×1024, 512×512, or other dimensions that may be appropriate for the AI engine to function in a better way.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example manual identification of patterns in a rasterized version of an image included in a design plan that correspond with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. A boundary within the context of a design plan may signify the presence of a wall. Using deep artificial neural networks, original architectural floor plans (along with any labeled boundaries) may be used to train AI models to make predictions about what is inside a boundary. In exemplary embodiments, the AI model may be given over ˜50,000 similar architectural floor plans to improve boundary-prediction capabilities.

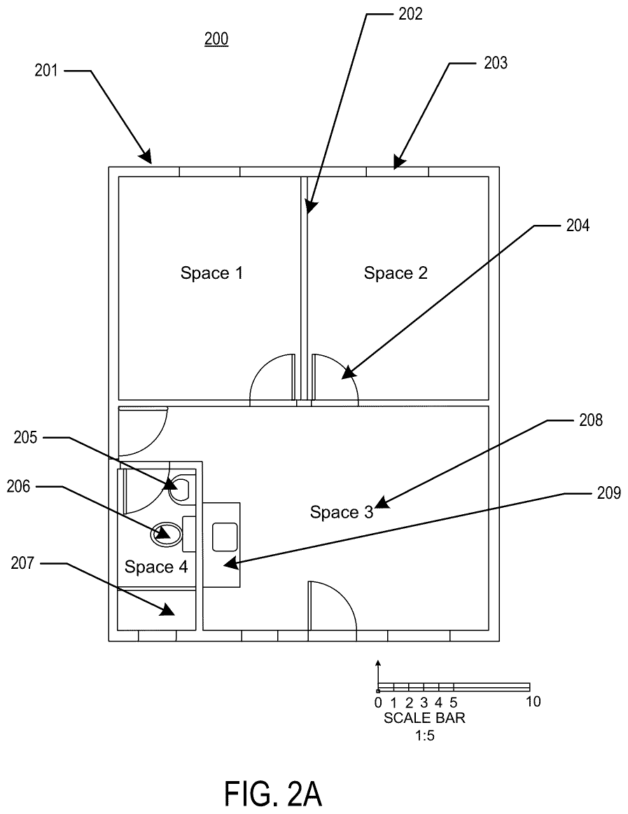

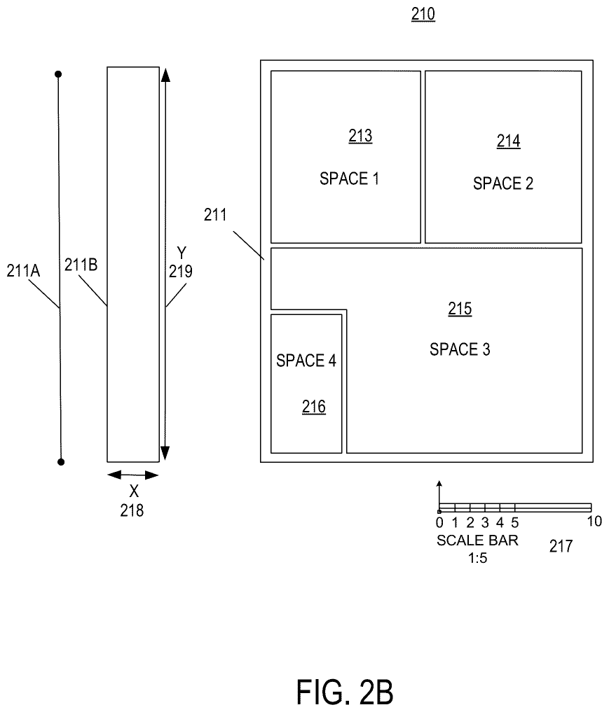

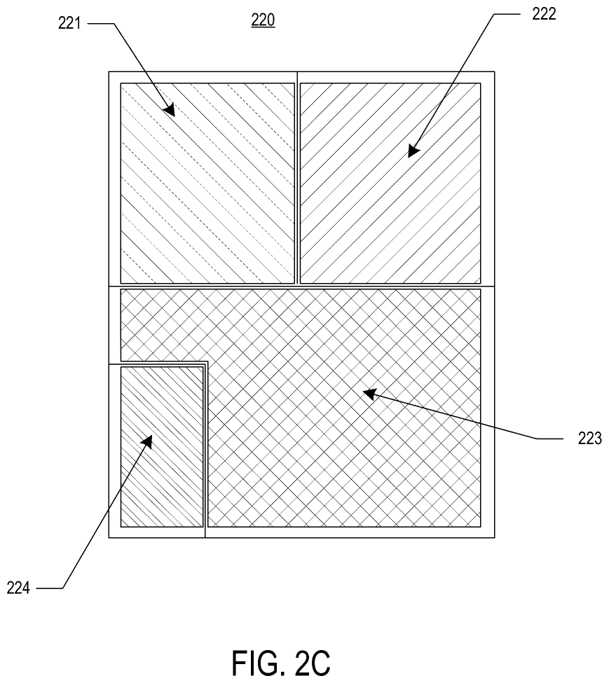

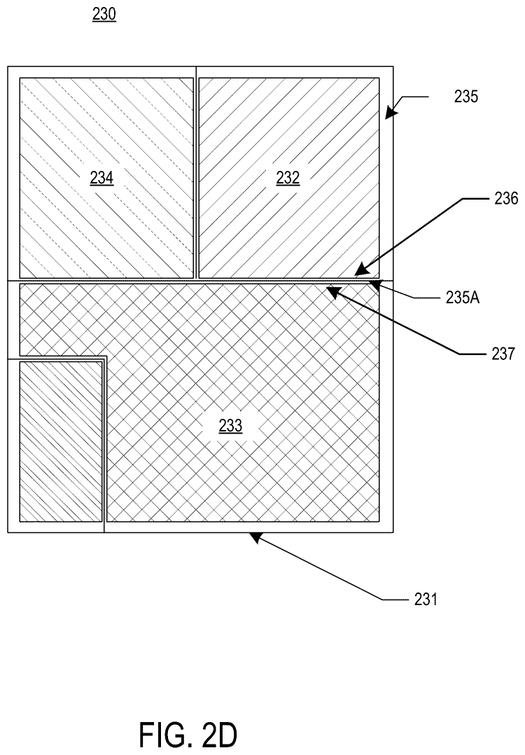

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. (An exemplary AI-processed two-dimensional reference that includes a design plan and/or a floorplan 210, with boundaries 211 predicted, is shown in FIG. 2B, based on the floorplan of FIG. 2A).

In still another aspect, in some embodiments, a controller may access data from various types of BIM and Computer Aided Drafting (CAD) design programs and import dimensional and shape aspects of select spaces or portions of the designs as they are related to a design plan.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, fixtures, duct work, wiring, piping, or other item included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shape.

At step 105, a scale (e.g., FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale or dimension for a particular image, building component, a wall, a boundary, a drawing or other two-dimensional reference. The drawing scale, may for example, be in inches: feet, centimeters: meters, or any other appropriate scale.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference (or design plan) and proportioned according to that length. The known length of the wall can be determined from the markings or text on the design plan or can be specified by a user as an input. A known length or width of any other building component can be determined or entered by the user. Based on such known length or width of one building component, the scale can be proportioned, and dimensions of other building components can be calculated.

At step 106, a controller is operative to generate an interactive user interface with dynamic components that may be manipulated by one or both of user interaction and automated processes. Any or all of the components in a user interface may be converted to a version that allows a user to modify an attribute of the components, such as the length, size, beginning point, end point, thickness, or other attribute. In some embodiments, a boundary may be treated as a component or a wall and manipulated in a similar manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 106A, in some embodiments, components presented in the interactive user interface may be analyzed by a user and refinements may be made to one or more components (e.g., size, shape and/or position of the component). In some embodiments, user modifications may also be input back to the AI engine to train the AI engine. User modifications provided back to the AI Engine may be referenced to make subsequent AI processes more accurate, efficient, fast, trained and/or enable additional types of AI processes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step transforms features such as windows, doorways, vias and the like to other features and may remove them and/or replace them as elements—such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types may include, for example, one or more of line segments, polygons, multiple line segments, multiple polygons, and combinations of line segments and polygons.

At step 108, a controller (such as, by way of non-limiting example, a cloud server) operative as an AI engine may create AI-predicted dynamic boundaries that are arranged to form a representation of the submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, or other purpose.

For example, a change in a boundary may make an area larger. The larger area may be a basis for an increase in occupancy load. The larger area may also result in a longer path from the furthest point in the defined area to a point of egress (e.g., if a user chooses to use a worst case in determining an egress route). Empowering users with flexibility, the present invention allows for seamless modifications to room boundaries, lines, and polygons, enabling the alteration of shapes and sizes to adhere to building codes with automated revision suggestions to design plans. This dynamic feature not only ensures compliance with regulatory standards but also caters to user preferences or priorities, allowing them to retain the opulence and aesthetic appeal of their spaces. Whether it is aligning with specific building code requirements or enhancing the overall user experience by accommodating individual tastes, the present invention offers a harmonious blend of functionality and personalization. Users can effortlessly tailor their rooms to meet both regulatory guidelines and their own vision, striking a balance between compliance and the creation of spaces that truly reflect their unique style and preferences.

At step 109, one or both of the user and an automated process on a controller may select (as a search query) a symbol or polygon shape provided by the the AI engine on the interactive user interface. In some embodiments, selection of the desired segment on the design plan may comprise utilizing a polygon shape tool accessible on the interactive user interface and enabling the user to drag and position a polygon shape onto a desired segment of the design plan (or two-dimensional representation). In other embodiments, the polygon shape tool accessible on the interactive user interface comprises employing the polygon shape tool for the user to choose from a range of polygon shapes or symbols provided by the AI engine within the user interface for selection and placement. Accordingly, by way of non-limiting example, a user may select the segment or portion by marking on or around the desired segment of the at least a portion of the design plan on the interactive user interface.

At step 110, the AI engine may perform a pixel-level analysis of the selected segment (or designated area, chosen portion, desired segment etc. are interchangeably used in the present invention). The AI processing of the pixel patterns in the pixel-level analysis, based upon the two-dimensional references and the selected segments/portions, may include mathematical analysis of polygons formed by joining select vectors included in the two-dimensional reference. The AI engine may also perform a comparison process to compare the selected segment with the dynamic components with the design plan or the at least a portion of the two-dimensional representation. The comparison process is performed to identify dynamic components matching the selected symbol or the polygon shape.

In some embodiments, the system may utilize pixel patterns and polygon patterns in sizing analysis of the selected segments of design plans. The sizing analysis (may be part of the pixel-level analysis) may comprise analyzing size of the selected segment with respect to the size of the area covered by the selected segment (or covered by the selected symbol or polygon shape). The system may incorporate a user-adjustable and/or AI-adjustable feature for sizing variations, utilizing percentage variation in pixel positions relative to other pixel positions within a defined window of the segment selection. It may involve convolutional filters for zero-shot and one-shot approaches, leveraging generative models and template matching. The zero-shot approach eliminates the necessity for users to define the shape or size of segments explicitly. It employs generative models or algorithms that predict and identify features within the design plans and the selected segments of the design plans without requiring specific prior input or definitions from the user. This method streamlines the process, enabling automatic feature recognition without detailed user instructions regarding segment shapes or dimensions. It pre-identifies distinct elements and smaller discrete objects, such as plumbing or electrical fixtures, that might be recognizable as dynamic components within the design plans. By utilizing generative models, it achieves precise identification and differentiation of various elements based on pixel count, allowing for accurate recognition of specific features within the design plan and within the selected segments of the design plans.

The One-Shot approach may employ template/segment matching, where users specify their preferences regarding boundaries (such as doors, toilets, plumbing fixtures). It may involve classifying walls based on selected symbols/segments and assigning attributes to indicate their load-bearing characteristics, streamlining the process of identifying and categorizing elements within the design plan according to a user-defined criteria.

Another embodiment may incorporate relative positioning of pixels, employing mathematical representations, algorithms, and vector-based approaches for analyzing distances, angles, and clustering vectors within the selected symbols/segments. The system aims for optimization based on quality, cost-effectiveness, durability, aesthetics, financial criteria, supply chain, labor costs, subcontractor selection, scope of work, location, equipment type, pixel spatial relevance, clearance codes, covering areas, floor, ceiling, paths, plumbing, gas/chemical lines, cables, electrical wiring, and a rule-based criteria. Users have the flexibility to designate or input segment measurements, encompassing parameters like length, area, volume, atmospheric volume, and relative height, which contribute to the system's precision in analysis. Segments can be specified through symbols or polygon shapes, either selected directly on the user interface or denoted as measurements within the interface, allowing for varied and customizable segment delineation. This versatile approach prioritizes user-defined preferences and customizable variables to streamline decision-making and planning.

At step 111, the AI engine residing on the controller, generates a list of dynamic components matching with the selected segment or polygon shape.

At step 112, the AI engine extracts a comprehensive data related to the dynamic components matching with the selected segment or polygon shape. The comprehensive data may be extracted from a database associated with the AI engine. The database may comprise one or more of: shapes, sizes, types, images, symbols, cost, brands, manufacturers, and qualities of the dynamic components. The comprehensive data may encompass dynamic component-specific details, the aggregate count of similar dynamic components within the entire design plan, associated material lists, material costs, labor costs for building and/or installing individual or multiple such dynamic components, facilitating streamlined planning and cost estimation. The comprehensive data may further include information related to the selected segment, including segment-specific details, counts of similar segments within the design plan, associated material lists, material costs, and labor costs for construction and installation.

At step 113, the AI engine may display on the interactive user interface the comprehensive data related to the dynamic components matching with the selected search symbol or polygon shape. In some embodiments of the present invention, the system can be integrated with advertisement platforms which deliver advertisements to users on the interactive user interfaces along with the comprehensive data related to the dynamic components matching with the selected search symbol or polygon shape. The advertisement may comprise but not limited to: components from particular brands that align with both the required quality standards and the user's budget, alternative components from other brands, comprehensive lists of materials associated with the matching dynamic components with pricing and purchase options, and even contact information or details of contractors, subcontractors, and architects available for hire. The purchase option may also include a cart to select items to purchase and an option to checkout and payments. The cart may add the items automatically based on a user specified budget. The user's quality standards and budget may be specified by the user through the interactive user interface.

Referring now to FIG. 1B, a high-level diagram illustrates components included in a system 120 that uses AI to generate an interactive user interface 125 and programmable apparatus (controller) 123 operative to execute method steps useful in one or both of: searching components included in a two-dimensional representation of a design plan of a building based on a symbol or a polygon shape and extracting comprehensive data related to a dynamic component included in a two-dimensional representation of a design plan.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, fixtures, real estate accouterments, and the like.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. Presentation of the two-dimensional reference may include, for example, scanning a hardcopy version of the two-dimensional document into electronic format and transmitting the electronic format to the controller 123 running the AI engine.

According to the present invention, the AI engine may use raw data, manipulated data, interpreted data, new data and data types generated from existing data. Data may include one or more of: text, image, numerical, pixel patterns, polygons, vectors, molecular, neural, digital, and analog data modalities.

Data sources may include one or more of: a user portal; Internet accessible resources; shipping data, fuel use tracking; manufacturer data; product data sheet; geolocation device, or other receptacle or generator of data related to material use in a building or other construction project.

AI engine processing may include one more of: converting image data to pixel patterns and/or polygon patterns, manipulating pixel patterns and/or polygon patterns, analyzing pixel patterns and/or polygon patterns, optical character recognition, alphanumeric analysis, symbol recognition and the like. Proposed action strategies, protocols and opportunities may be associated with an ascertained state.

The present invention provides for the deployment of computational frameworks combining disparate aspects of technology to perform tasks that are beyond the ability of traditional design and build systems or human intelligence. These systems aggregate large volumes of disparate data that may or may not be intuitively linked to building design, carbon footprint, eco-friendliness, compliance codes, supply chain availability, anticipated ambient climate conditions, measured ambient climate conditions, building activities, or other data source, and utilize multiple modalities data manipulation, algorithms, and statistical models to generate proposed action strategies for a patient (or group of similarly situated patients). Modalities of data manipulation may include, but are not limited to:

Machine Learning (ML): A subset of AI where systems learn from data. Instead of being explicitly programmed, they adjust their operations to optimize for a certain outcome based on the input they receive.

Deep Learning: A subfield of ML using neural networks with many layers (hence “deep”) to analyze various factors of data, such as, for example, convolutional neural networks (CNNs) used in image recognition. For example, convolutional neural networks may receive as input image data from scans of various types and generate pixel patterns representative of the scans. The pixel patterns may be compared to a library of other pixel patterns and/or manipulated to emulate progression of a disease state and/or a treatment protocol over time.

Natural Language Processing (NLP): Allows systems to understand, interpret, and generate human language. NLP may provide interpretations of voice data. Voice data may be made accessible, for example, via recording made during design plan review and assessment and/or during supply chain activities.

Robotics: Robots may operate using AI principles, enabling the robots to perform tasks in accurate, specific, and consistent ways. Robots may also be utilized during data collection, such as during building scans (e.g., 3D image acquisition scans), as built measurement acquisition, infrared heat image acquisition and the like.

Knowledge Representation: The methods and apparatus taught herein may receive data in a native or enhanced state and manipulate and transform the received data into a machine learning understandable form.

Reasoning: The methods and apparatus taught herein may solve deploy logical deduction via expert systems and the like to facilitate decision-making.

Perception: The methods and apparatus taught herein may use algorithms and complex relational processes that allow machines to interpret disparate data sets, including image data, sound data, and alphanumeric data.

Apparatus and methods may be arranged to form one or more of: Neural Networks; Genetic Algorithms; Expert Systems; and Reinforcement Learning.

In some embodiments, GPUs may be used to accomplish large-scale machine learning models using parallel processing capabilities. Hardware accelerators may be utilized for deep learning tasks. In some embodiments, tensor processing units and/or neuromorphic computing mechanisms may be used to analyze data sets. Cloud platforms may be used with AI processes, such as deep learning that require significant computational resources.

Electronic and/or electromechanical apparatus may provide data to be processed using the methods and apparatus presented herein. Apparatus may include, by way of nonlimiting example, one or more of: three-dimensional (3D) image scans, heat imaging acquisition, design plan scanners, building monitoring electronic sensors, drone based electronic scans, satellite-based data acquisition or other means of acquiring data that may be transformed into digital and/or analog data sets.

Some AI Engine generated treatment strategies may include suggested courses of action that may be weighted based upon one or more of: projected effectiveness; timing, geographic location and a material's ability to be transported; cost; and project criticality, including timeline relative to other actions and/or tasks that must be completed, such as for example, a sequence of construction steps, inspections, and financing requirements.

The controller is operative to generate a user interface 125 on a user computing device 126. The user computing device may include a smart device, workstation, tablet, laptop or other user equipment with a processor, storage. and display.

The user interface 125 includes a reproduction of the pictorial representation 122 and an overlay 124 with one or more user manipulatable components, such as, by way of non-limiting example: boundaries, line segments, polygons, images, icons, points, and the like. The line segments may have calculated lengths that may be mathematically manipulated and/or summarized. Aspects such as polygons, line segments, shapes, icons, and points may be counted, added, subtracted, extrapolated, and have other functions performed on them.

In addition, renditions of the user interface 125 may be created and saved, and/or communicated to other users, or controllers, compared to subsequent interface renditions, archived, and/or submitted to additional AI analysis.

In some embodiments, a first user interface 125 rendition may be modified by a user to create a second user interface 125 and submitted to AI analysis to perform one or both of: searching components included in a two-dimensional representation of a design plan of a building based on a symbol or a polygon shape and extracting comprehensive data related to a dynamic component included in a two-dimensional representation of a design plan.

Referring now to FIG. 1C, the AI engine may provide flexibility to mark on or around desired segments or portions of the design plan directly within the interactive user interface. The system allows users the choice to designate or opt or mark a symbol or a shape representing the desired segment on the design plan for conducting the comprehensive data extraction process of the current invention. This is achieved by indicating or marking the desired segment on the design plan within the design plan using a computer mouse pointer on the interactive user interface. For example, a user can select a desired segment 130 of a design plan with a mouse pointer (or any other pointing device) from a Point A to a Point B. The AI engine takes this selection as a search query and performs the functions or processes as discussed for FIG. 1A above. In an alternative embodiment, the present invention provides a polygon shape tool accessible on the interactive user interface as shown in FIG. 1D, allowing the positioning of various polygon shapes onto desired segments of the design plan. This tool offers a selection of polygon shapes sourced from the AI engine, enhancing precision in segment placement. For example, when employing the polygon shape tool, users may choose from a range of polygon shapes or symbols represented as but not limited to: a1, a2, a3, a4, a5, a6, and a7 as shown in the FIG. 1D. These polygon shapes or symbols can be of any type, shape, and size provided by the AI engine within the user interface for selection and placement. For instance, a user may select a polygon shape or symbol a1 and drag it to place on a desired segment P1 of at least a portion (static pictorial representation 122) of the two-dimensional reference/representation 121. Based on this selection and placement of a particular polygon shape or symbol, the AI engine performs the processes as outlined above for FIG. 1A.

In some embodiments, a user interface may be representative of one or more aspects include in a design plan or other two dimensional references. A user action may identify portions of the design plan. The identified portions may correlate with one or both of: pixel patterns, lines, and polygons included in a representation of the design plan or other two-dimensional reference.

In some embodiments of the invention, the segments within the design plan may comprise one or more of: polygon shapes and specific architectural components like doors, windows, stairwells, walls, floors, ceilings, ramps, columns, beams, roofs, skylights, facades, and HVAC elements.

Referring now to FIGS. 1E and 1F, the interactive user interface displays the comprehensive data 170 related to the dynamic components matching with the symbol, desired segment, or the selected polygon shape. Each of the comprehensive data 170 can be selected by the user to view further options in the pop-up window 175 related to a selected comprehensive data 170. The comprehensive data 170 extracted for the identified dynamic components may include details such as component names, types, quantities, and associated costs. When a user selects a comprehensive data 170 e.g., an associated cost, a pop-up window 175 may appear which shows pricing details related to a linked dynamic component. The pop-up window 175 may also show advertisements for the linked dynamic component from particular brands that align with both the required quality standards and the user's budget. The pop-up window 175 may also present the user with an option to enter the required quality standards and the budget.
A. By way of non-limiting examples, according to the present invention, a design plan may be received as a static image two-dimensional reference. The design plan may be described using lines and arcs, and represent architectural layouts in a simplified geometrical way. In such a representation, architectural elements, such as, by way of non-limiting example: walls, doors, windows, and architectural details, may be shown using straight lines (for linear elements) and arcs (for curved elements). A floorplan interpreted in terms of lines and arcs and/or patterns of pixels may include one or more of:
B. Exterior Walls: typically represented by thick lines. The thickness of a line may indicate the wall's thickness.
C. Interior Walls: which may be shown as slightly thinner lines compared to exterior walls, representing partitions or dividers within a space or other interior area.
D. Hinged Doors: a straight line representing a door's location and an arc showing the door's swing direction and extent.
E. Sliding Doors: two parallel lines (representing door panels) may include an arrow or dashed line indicating a sliding direction.
F. Double Doors: two straight lines representing door panels with arcs indicating each door's swing direction.
G. Which may, for example, be represented as thin lines or breaks in walls, sometimes with a zigzag line to indicate a window's presence or with a double line indicating a double-pane window.
H. Straight Stairs: a series of parallel lines showing steps. Often, an arrow may be used to indicate the upward direction.
I. Spiral Stairs: may be represented using concentric arcs or circles, showing the curvature of the stairwell.
J. Cabinets, Countertops, Islands: straight lines and arcs may represent a shape and placement of cabinets, countertops, and islands.
K. Sinks, Bathtubs: may typically be represented using a combination of lines and arcs to depict their shapes.
L. Rounded Corners: instead of sharp, angular intersections between walls, arcs are used to show the curve.
M. Circular Rooms or Features: may be represented using full circles or arcs.
N. Electrical: may be shown with dotted lines or specific symbols indicating outlets, switches, and fixtures.
O. Plumbing: may be represented via dotted or dashed lines to represent hidden plumbing within walls or under floors.

When interpreting or representing a floorplan using lines and arcs, conventions used in architectural drawings may be referenced. In some embodiments, a legend or key that describes what each line, arc, or symbol means, may ensure clarity in understanding the design.

In some embodiments of the invention, the AI engine may present on the interactive user interface various other options 180 such as but not limited to: a particular approach (e.g., zero-shot or one-shot approach) to process the search query or comprehensive data extraction function, and various polygon shapes or symbols to select from. The AI engine may also present on the interactive user interface a sub-section 190 to interact with the design plan. The sub-section 190 may also comprise a comprehensive list of materials with pricing and purchasing options, along with contact details of available contractors, subcontractors, and architects to hire. The contractors, subcontractors and architects may be presented on the user interface based on their previous experience in the similar work areas involving similar dynamic components or design plans.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value.

In some embodiments, a recognition step may function to replace or ignore a feature. For example, for a task goal of the result shown in FIG. 2B, features such as windows 203, and doorways 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated.

Referring now to FIG. 2B, a boundary 211 is illustrated around a grouping of defined spaces 213-216. Spaces are areas within a boundary (which may include, but are not limited to rooms, hallways, stairwells etc.).

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example in creating a three-dimensional representation of a design plan.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature and the centroid points may be counted, summarized, subtracted, averaged, or otherwise included in mathematical processes.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

Referring now to FIG. 2C, a user interface 220 is illustrated with multiple regions 221-224. The multiple regions 221-224 may be presented via different hatch representations or other distinguishing pattern (in some embodiments regions may also be represented as various colors etc.). During training of AI engines, and in some embodiments, when a submitted design drawing includes highly customized or unique features, a user may wish to adjust an automated identification of boundaries and automated filling of space within the boundaries.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, of change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification.

Discrete regions may be regions associated with an estimation function. A region that is contained within a defined wall feature may be treated in different ways such as ignoring all area within a boundary, to counting all area within a boundary (even though regions do not include boundaries). If the AI engine counts the area, it may also make an automated decision on how to allocate the region to an adjacent region or regions that the region defines.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance rank may share space, or regions with higher dominance rank may be automatically assigned to a boundary. In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified. In some embodiments, the incorporation of a dominance rank may be instrumental in delivering automated suggestions for the revision of design plans. The dominance rank may serve as a strategic guide, steering the focus towards regions of higher dominance rank. For instance, regions with a higher dominance rank are recommended to remain as unchanged as possible in the suggested revisions besides making sure that the revised designs of the regions comply with the building codes. The comprehensive data related to the dynamic components matching with the search query may also be presented based on the dominance rank of regions, dynamic components representing the regions, and the selected segments on the design plans. This approach prioritizes regions with a higher dominance rank on the overall design, ensuring that modifications align with both regulatory requirements and the foundational elements that contribute significantly to the design's integrity.

In some embodiments, an area 235A between interior boundaries 236-237 and an exterior boundary 235 may be fully assigned to an adjacent region 232-234. An area 235A between interior boundaries 236-237 may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant, based upon parameters such as its area, its perimeter, its exterior perimeter, its interior perimeter, and the like. Parameters may also be based upon items that are automatically counted using AI analysis of pixel patterns that identifies a pattern as an item, such as, by way of non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to a prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIG. two dimensional. In various embodiments, different calculated features are included in a user interface floorplan model 231 such as features representing aspects of a wall, such as, for example, center lines, the extents of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence comprehensive data extraction process as discussed above for FIG. 1A.

Once boundaries have been defined a variety of calculations may be made by the system. A controller may be operative to perform method steps resulting in calculation of a variable representative of a floorplan area, which in some embodiments may be performed by integrating areas between different line features that define the regions.

Alternatively, or in addition to method steps operative to calculate a value for a variable representative of an area, a controller may be operative to generate a value for element lengths, which values may also be calculated. For example, if ceiling heights are measured, presented in drawings, or otherwise determined, then volume for the room and surface area calculations for the walls may be made. There may be numerous dimensional calculations that may be made based on the different types of model output and the user-inputted calibration factors and other parameters entered by the user.

In some embodiments, a controller may be provided with two dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects.

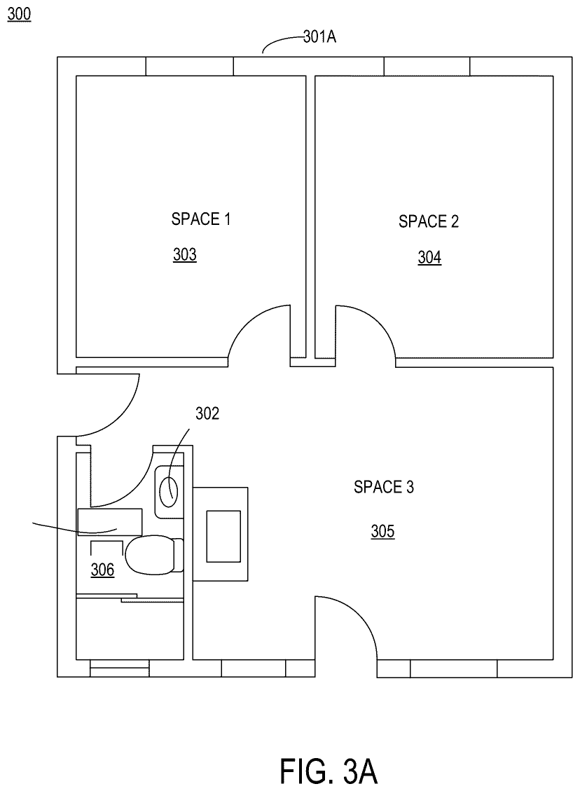

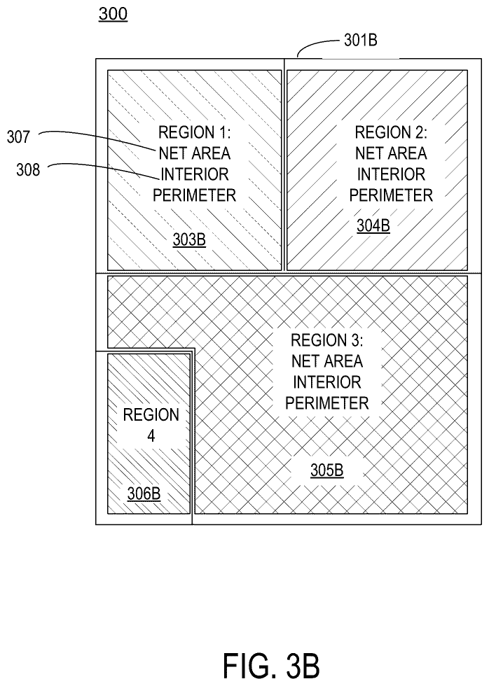

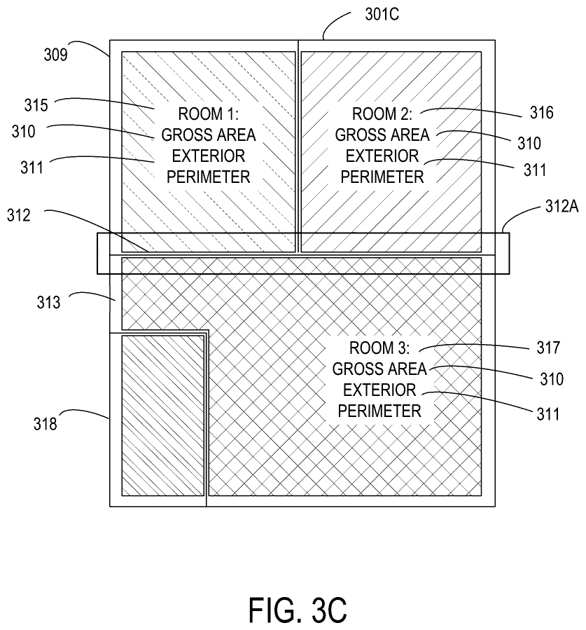

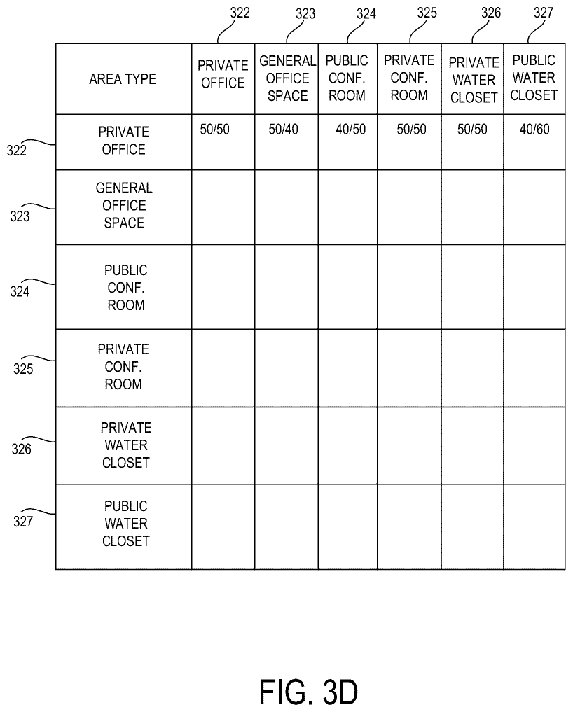

Referring now to FIGS. 3A-3C a user interface 300 may generate multiple different user views, each view has different aspects related to the two-dimensional reference drawing inputted. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and may be used to generate an estimate for completion of a project illustrated by, or otherwise represented by, the two-dimensional reference.

Referring now to FIG. 3B, in the user interface 300 a user may specify to a controller that one of multiple views available is to be presented via the interface. For example, a user may designate via an interactive portion of a screen displaying the user interface 300 that a region view 301B be presented. The region view 301B may identify one or more regions and/or spaces 303B-306B identified via processing by a controller, such as for example via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material.

Referring now to FIG. 3C, a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space but, may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the present invention calculates an area bounded within a series of polygon elements (such as, for example, using mathematical principals or via pixel counting processes), and/or line segments.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B subsequently have regions assigned as “Rooms” in FIG. 3C.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example adjacent areas (e.g., area 315 and area 317 or area 317 and area 318), the hierarchical relationship may be used to generate a dominance ranking of one area over another area, or to ascertain factors useful in one or both of: searching components included in a two-dimensional representation of a design plan of a building based on a symbol or a polygon shape and extracting the comprehensive data related to a dynamic component included in a two-dimensional representation of a design plan. For example, a dominance ranking may allocate space used to calculate one or more of: an occupancy load; a width and/or area of an egress path; a width and/or area of a common path; a length of a dead end; egress capacity; and travel distance from a furthest point. In this context, regions assigned a higher dominance ranking are designated to be inherently associated with elevated safety standards.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on.

Dominance associated with various areas or regions may be systemic throughout a project, according to customer preference, indicated on a two-dimensional reference by two-dimensional reference basis or another defined basis.

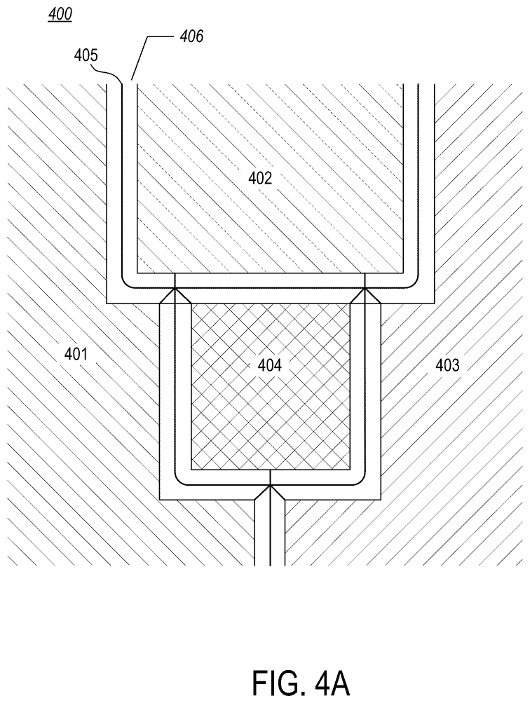

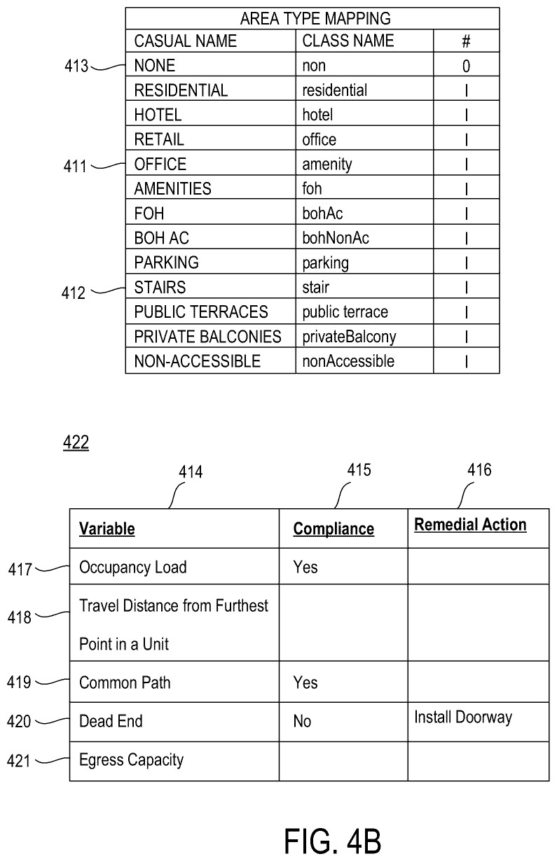

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect one or both of: one or both of: searching components included in a two-dimensional representation of a design plan of a building based on a symbol or a polygon shape and extracting comprehensive data related to a dynamic component included in a two-dimensional representation of a design plan. For example, as illustrated, variables 417-421 may include occupancy load 417, travel distance from a furthest point 418, Common path 419, dead end 420, and egress capacity 421.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes for automatic classification of regions from an input drawing.

An AI engine or other process executed by a controller may be refined, trained, or otherwise instructed to utilize a number of recognized characteristics to accomplish area classification. For example, an AI engine may base predictions for a type “/”category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

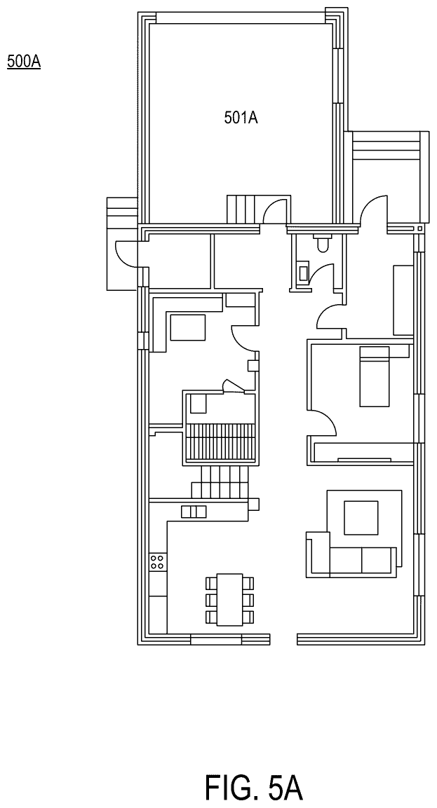

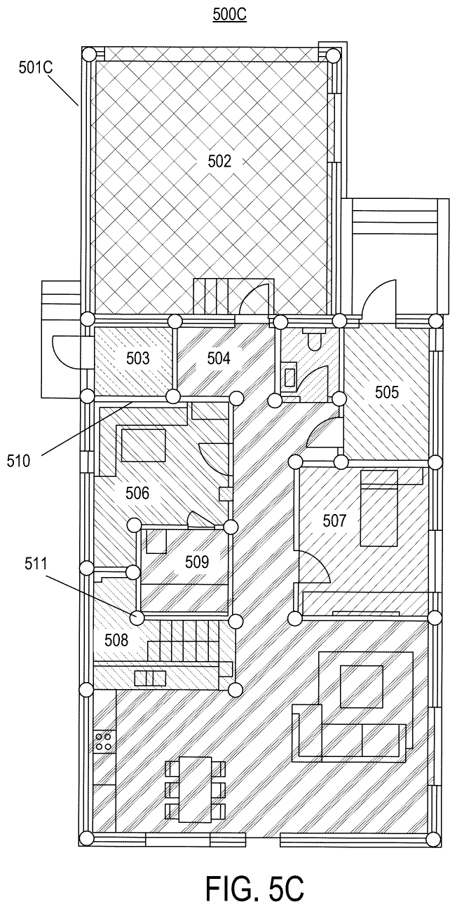

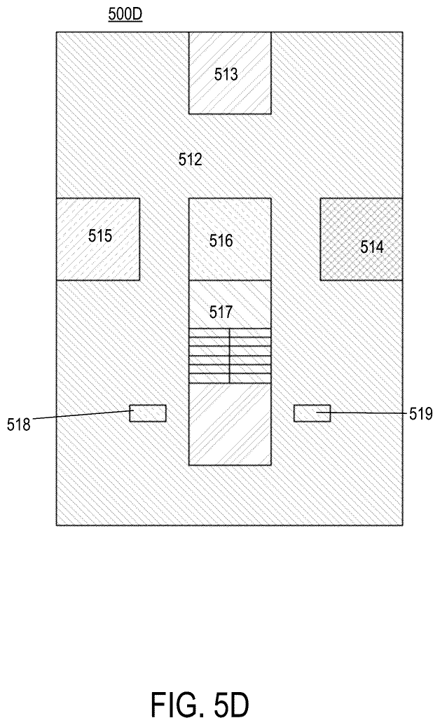

Referring now to FIGS. 5A-5D, a progressive series of outputs that may be included in various user interface are illustrated and provides examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of regions; spaces; patterned portions; line segments; polygons; symbols; icons or other portions of the user interfaces may be assembled and presented in a user output and our user interface, or as input into another automated process. In some embodiments, selection or marking of the desired segments may be incorporated on the user interfaces 500A-500D as shown in FIGS. 5A-5D.

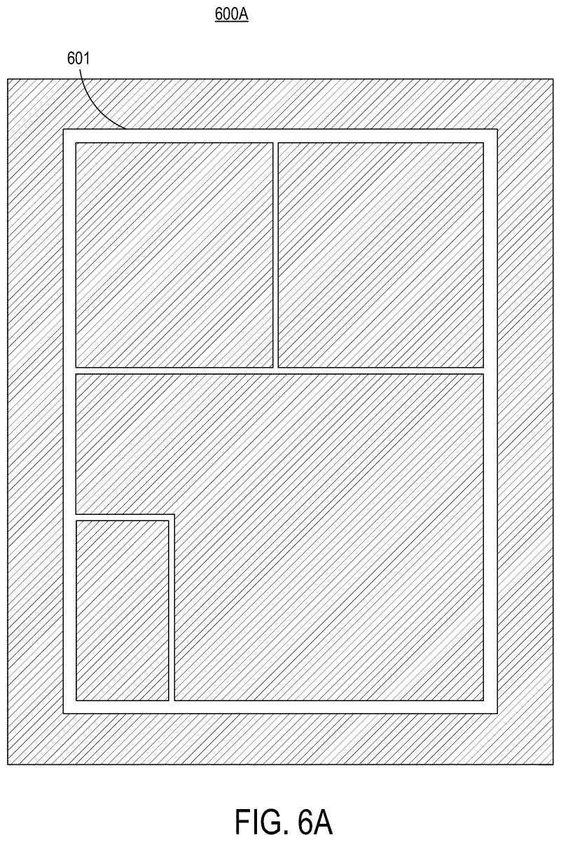

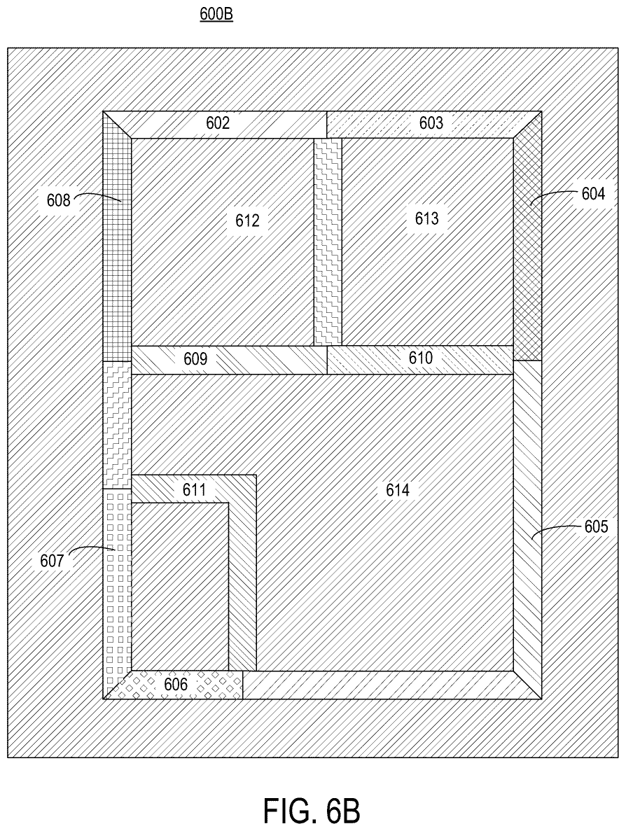

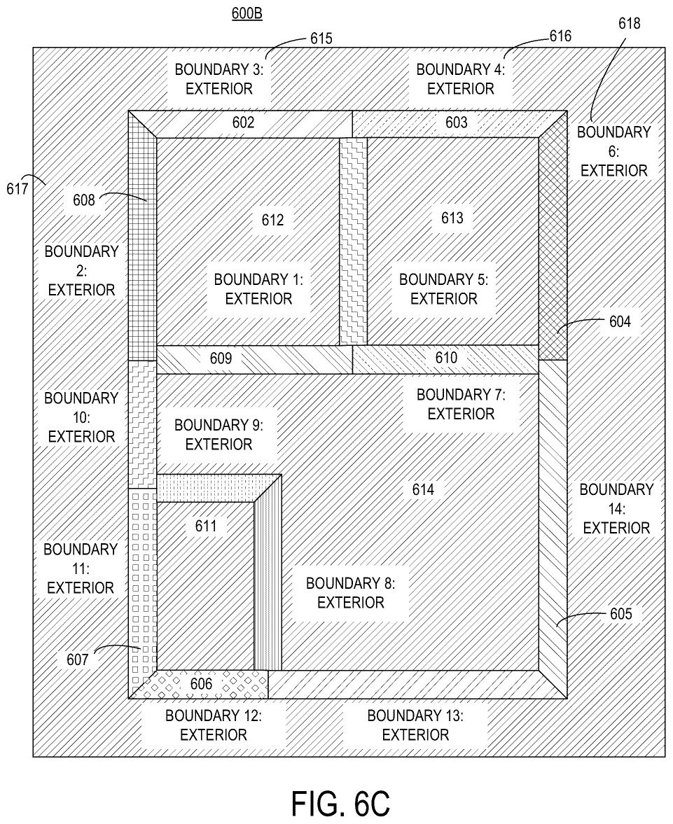

Referring now to FIGS. 6A-6C, in some embodiments, automated and/or user-initiated processes may include refinement of regions, spaces, or areas may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

In some embodiments, functionality may be allocated to classified individual line segments 602-611, such as, by way of non-limiting example, a process that generates an estimated materials list for a region or an area defined by a boundary, based on the regions or area's characteristics and its classification. In some embodiments, selection or marking of the desired segments may be incorporated on the user interfaces 600A-600C as shown in FIGS. 6A-6C.

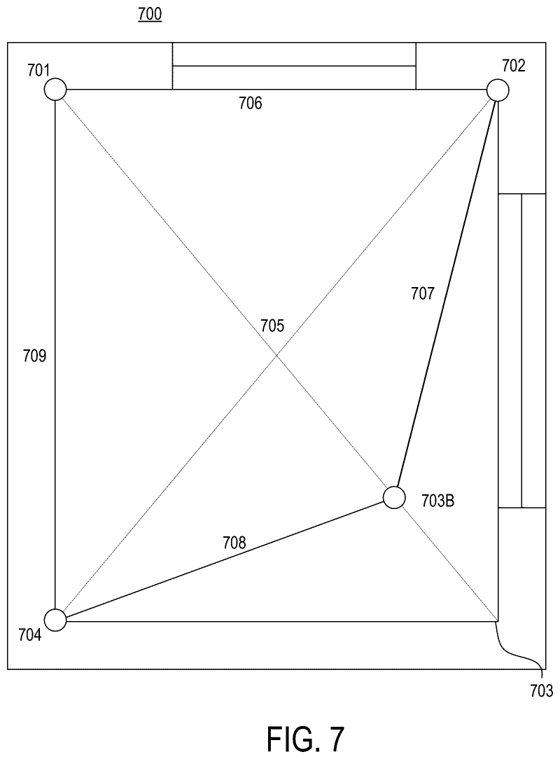

Referring now to FIG. 7 in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance. Additionally, in some embodiments, user interaction involving positioning of a vertex 701-704 may comprise selection of a desired segment of a design plan by marking and combining a plurality of vertex points similar to vertex 701-704.

### Model Training Procedures

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

### Estimation Automation

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting, and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied on a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Additionally, a text input or other narrative may be recognized to provide more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, a user interface or other output display or on reports, different layers may be illustrated at different times along with associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of codes, standards and the like and review the discovered design elements, selected segments, or matching dynamic components for comprehensive data extraction related to a dynamic component matching with a search query and included in a two-dimensional representation of a design plan. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

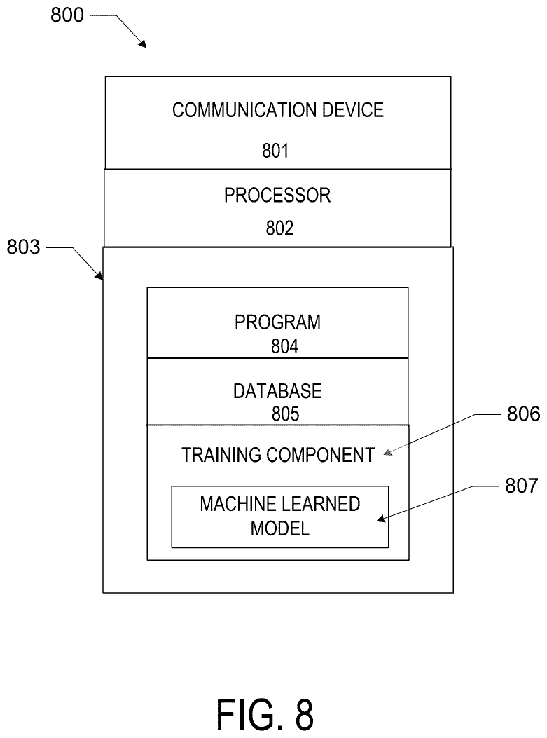

Referring now to FIG. 8 an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

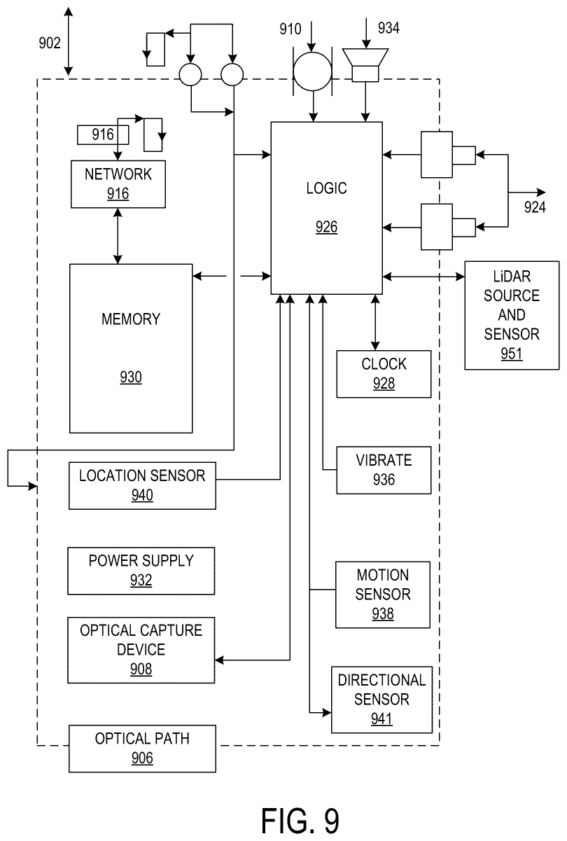

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. The microphone 910 may also be utilized by users to provide commands related to the comprehensive data extraction processes of the present invention. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record time and strength of returned signal that is reflected off of surfaces in the environment of the mobile device 902. In some embodiments, as have been described herein, a 2-dimensional drawing or representation may be used as the input data source, and vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

User Interface with Single and Multiple Layers

In some embodiments, the user may be given access to movement of boundary elements and vertices of boundary elements. In examples where lines or vectors are used to represent boundaries and surrounding area, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a feature or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

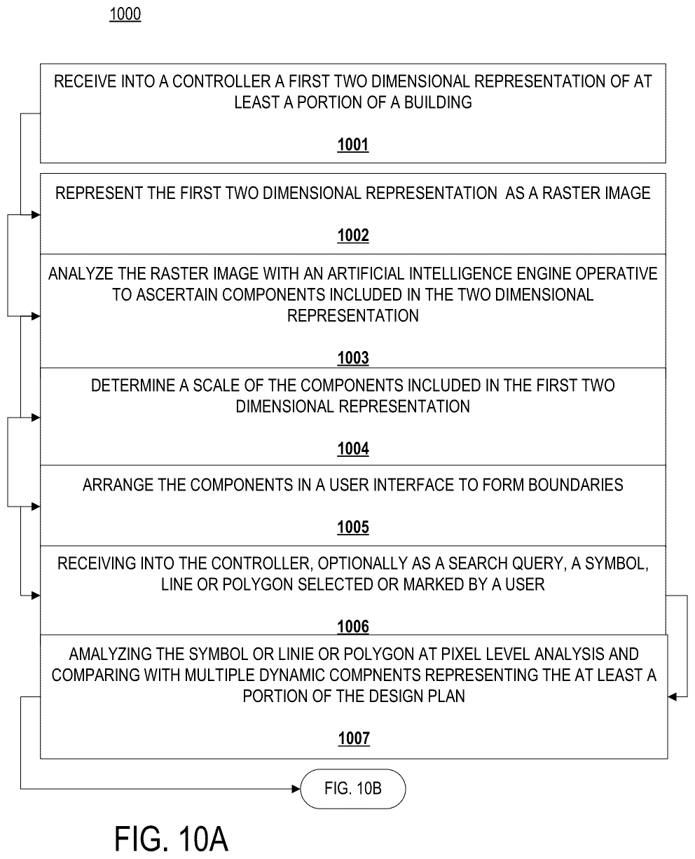

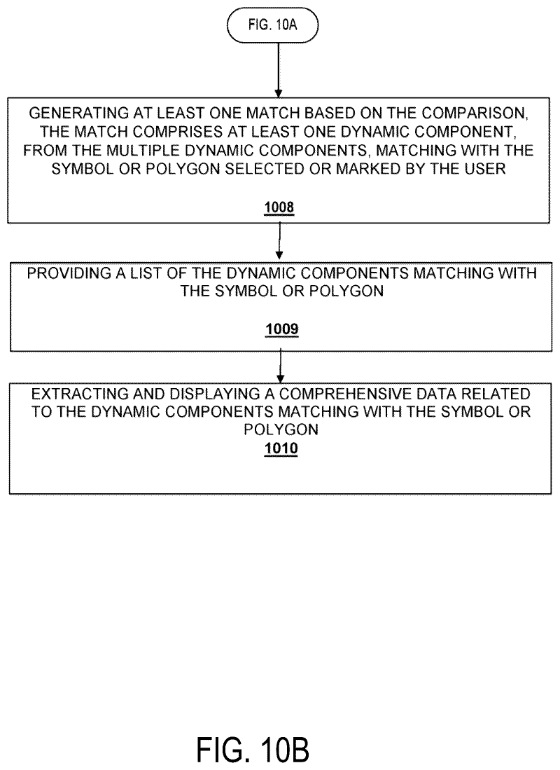

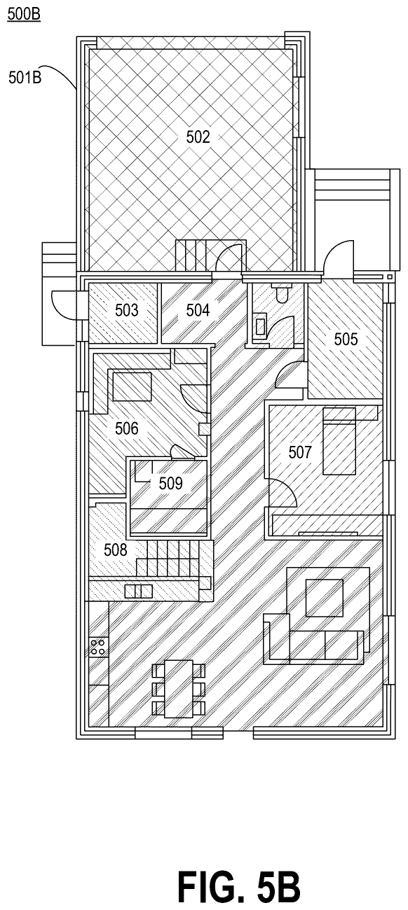

Referring now to FIGS. 10A-10B method steps are illustrated for comprehensive data extraction processes based upon artificial intelligence analysis of a design plan and the desired segment of the design plan according to some embodiments of the present invention. At step 1001, the method includes receiving into a controller a design plan (or a first two-dimensional representation) of at least a portion of a building. As described above, the design plan may include an architectural drawing, floor plan, design drawing and the like.

At step 1002, the portion of a design plan (or a first two-dimensional representation) may be represented as a raster image or other image type that is conducive to artificial intelligence analysis, such as, for example, a pixel-based drawing.

At step 1003, the raster image may be analyzed with an artificial intelligence engine that is operative on a controller to ascertain components included in the design plan.

At step 1004, a scale of components included in the design plan may be determined. The scale may be determined, for example via a scale indicator or ruler included in the design plan, or inclusion in the design plan of a component of a known dimension.

At step 1005, a user interface may be generated that includes at least some of the multiple components.

At step 1006, the controller receives a symbol or polygon shape selected by a user as a search query for the comprehensive data extraction process of the present invention. The symbol or polygon shape may be selected from a plurality of polygon shapes as presented in the FIG. 1D. The controller may also receive the desired segment (as a search query) of a design plan marked by the user by marking around or on the desired segment directly within the user interface as presented in the FIG. 1C.

At step 1007, the controller (and the AI engine) analyzes the search query (i.e., selected or marked symbol, polygon shape or a desired segment) at the pixel-level analysis as disclosed in the present invention. The controller further compares the search query with the multiple dynamic components of the two-dimensional representation to identify a match.

At step 1008, the controller generates at least one match based on the comparison at step 1007, wherein the match may comprise at least one dynamic component, from the multiple dynamic components, matching with the search query selected, marked, or input by the user.

At step 1009, the controller provides a list of the dynamic components matching with the search query or the selected segment. The segment or search query may be selected or entered by the user as disclosed in the FIGS. 1C & 1D.

At step 1010, the controller extracts comprehensive or detailed data related to the dynamic components matching with the search query or the selected segment and displays comprehensive data on the interactive user interface. Along with the comprehensive data, the controller may also display other information within the scope of this invention.

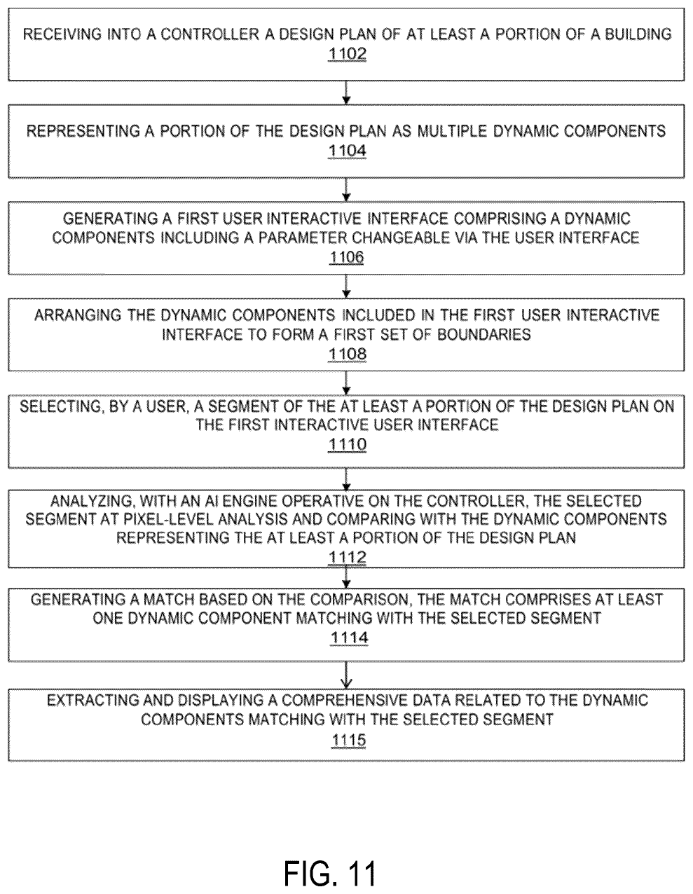

Referring now to FIG. 11, a system including one or more controllers can be configured to perform particular operations or actions by virtue of having executable software, firmware, hardware, or a combination of them that in operation cause the controllers to be operative to perform method steps for one or both of: searching components included in a two-dimensional representation of a design plan of a building based on a symbol or a polygon shape and extracting comprehensive data related to a dynamic component included in a two-dimensional representation of a design plan.

At step 1102, receiving into a controller a design plan of at least a portion of a building.

At step 1104, the method may include representing a portion of the design plan as multiple dynamic components.

At step 1106, the method may include generating a first user interactive interface including at least some of the multiple dynamic components representing a portion of the design plan, each dynamic component including a parameter changeable via the user interactive interface.

At step 1108, the method may include arranging the dynamic components included in the first user interactive interface to form a first set of boundaries, the first set of boundaries including a respective length and area, and the first set of boundaries defining at least a portion of a first unit.

At step 1110, the method may include selecting, by the user, a segment of the at least a portion of the design plan on the interactive user interface (as shown in FIGS. 1C & 1D).

At step 1112, the method may include analyzing, with an AI engine operative on the controller, the selected segment at the pixel-level analysis and comparing with the multiple dynamic components representing the at least a portion of the design plan.

At step 1114, the method may include generating at least one match based on the comparison at step 1112, wherein the match comprises at least one dynamic component, from the multiple dynamic components, matching with the selected segment or the search query.

At step 1115, the method may include at least one of: providing a list of the dynamic components matching with the selected segment, extracting a comprehensive data related to the dynamic components matching with the selected segment, and displaying on the interactive user interface the comprehensive data related to the dynamic components matching with the selected segment (or the search query).

Implementations may include one or more of the following features. The method additionally comprises determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the user interactive interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via a user interactive interface to modify a parameter of the line segment, and the method further includes the step of modifying the parameter of the line segment based upon the instruction received via the interactive user interface. The parameter of the line segment may include a length of the line segment and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference (i.e., first design plan) and the second two-dimensional reference (i.e., second design plan), respectively.

Methods of practice may additionally include the steps of: determining whether a design plan received into the controller includes a vector image, and if one of the first and the second design plan received into the controller includes a vector image, converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the user interactive interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit (e.g., room or a portion of a building), or other defined space. A change in area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of one or both of: searching components included in a two-dimensional representation of a design plan of a building based on a symbol or a polygon shape and extracting comprehensive data related to a dynamic component included in a two-dimensional representation of a design plan.

A dynamic component may include a line segment and/or vector, and the method may further include the steps of: receiving an instruction via the user interactive interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor (e.g., based upon one or both of: searching components included in a two-dimensional representation of a design plan of a building based on a symbol or a polygon shape and extracting comprehensive data related to a dynamic component included in a two-dimensional representation of a design plan).

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to perform methods steps of one or both of: searching components included in a two-dimensional representation of a design plan of a building based on a symbol or a polygon shape and extracting comprehensive data related to a dynamic component included in a two-dimensional representation of a design plan.

In another aspect, in some embodiments, suggested modifications may be ranked according to a priority ranking of features input via a user interface. For example, a user may input priority rankings that dictate that a number of a certain type of room or unit must be maintained above a threshold within the plan, such as, for example, the plan must include: ten residential units, each unit with three bedrooms and two bathrooms and a kitchen a living room; or at least four units with three bedrooms each; a second priority may include room sizes of a minimum and/o maximum size; a third priority may include a washer and dryer area; a fourth priority may include a common area of a minimum size; and other prioritized attributes to be included in a building design. AI and/or user input may modify a design, or a selected segment of the design, based on the comprehensive data related to the matching dynamic components. In some instances, the comprehensive data extraction process of the present invention may incorporate user-defined priorities to process the selected segments and the multiple dynamic components of the design plans.

Still further, in some embodiments, the controller may assess how assignment of different classes of space to one or more designated areas may alter conformance of a design with a specified code. Furthermore, in some embodiments, particular attributes of a building may be analyzed based upon laws or regulations in effect within a geopolitical boundary encompassing the building. In some embodiments, multiple disparate user interfaces may be used to communicate calculated parameters associated with determined attributes and the comprehensive data in order to give a user an improved experience.

### Additional Methods of Model Formation

There may be alternative methods of receiving data from various sources that can be used to generate a design or to supplement a design created in the manners as have been described previously. For example, the system may receive an architectural file with intelligent features of various kinds which will be discussed in further detail following. The present system may operate in concert with a BIM or CAD design system for example as an add-in to these design systems and then the present system may have access to design elements, location data and the like directly. In other examples, the present system may access BIM or CAD design system data by loading datafiles from said systems. In still further examples, the present system may operate to capture data from display screens that are displaying designs from the said BIM or CAD design systems. As an additional example, the present compliance assessment system exhibits its versatility by harmoniously integrating with prominent design frameworks like BIM or CAD. This integration facilitates a proactive approach to evaluate the compliance of building designs in the nascent or initial stages of the creative process, considering an array of potential building codes. This early-stage assessment not only ensures that the design in progress aligns with regulatory standards but also serves as a strategic time-saving measure, optimizing the efficiency of the overall design workflow. The synergy between compliance analysis and design systems not only enhances the precision of the evaluation at early stages but also contributes to a more streamlined and resource-efficient architectural and engineering endeavour.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

### Glossary

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Building Information Modeling” sometimes referred to as “BIM,” as used herein.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The terms “design plan,” “building plan,” “building design,” “floor plan,” “two-dimensional reference,” “two-dimensional representation,” or simply “design” are used interchangeably, often referring to the same or similar concepts in the context of architectural or construction documentation.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, they should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood that the drawings and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/of” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

What is claimed is:

1. A method for searching components included in a two-dimensional representation of a design plan of a building based on a symbol, the method comprising the steps of:
a. receiving, into a controller, a two-dimensional representation of a design plan of at least a portion of the building;
b. representing at least one portion of the design plan as multiple dynamic components;
c. generating an interactive user interface comprising at least some of the multiple dynamic components representing the at least one portion of the design plan, each of the multiple dynamic components including a parameter changeable via the interactive user interface;
d. receiving, as a search query, into the controller, the symbol selected by a user;
e. analyzing the symbol at pixel-level analysis and comparing with the multiple dynamic components representing the at least one portion of the design plan;
f. generating at least one match based on the comparison at step e, wherein the at least one match comprises at least one dynamic component, from the multiple dynamic components, matching with the symbol selected by the user;
g. providing a list of dynamic components matching with the symbol;
h. extracting a comprehensive data related to the dynamic components matching with the symbol; and
i. displaying on the interactive user interface the comprehensive data related to the dynamic components matching with the symbol.

2. The method of claim 1, wherein the comprehensive data comprises at least one of: name of the dynamic components matching with the symbol, type of the dynamic components matching with the symbol, number of the dynamic components matching with the symbol, and cost associated with the dynamic components matching with the symbol.

3. The method of claim 1, further comprising a step of displaying at least one automated suggestion related to the dynamic components matching with the symbol.

4. The method of claim 3, wherein the at least one automated suggestion comprises at least one of: a proposed design alteration, a dimension adjustment, a length and width suggestion, a material specification including recommended brands, a compliance adherence advice, and a safety enhancement advice.

5. The method of claim 1, wherein the symbol comprises at least one of: a polygon shape, a door, a window, a stairwell, a wall, a floor, a ceiling, a ramp, a column, a beam, a roof, a skylight, a facade, and an HVAC component.

6. The method of claim 1, further comprising a step of displaying on the interactive user interface an advertisement comprising at least one of: a dynamic component from a particular brand, an alternative dynamic component from a different brand, a list of materials with pricing and purchase options, and a contact information of a contractor available for hire, and a contact information of an architect available for hire.

7. The method of claim 6, wherein the dynamic component from the particular brand and the alternative dynamic component from the different brand align with one or both a required quality standard and a budget of the user.

8. The method of claim 1, wherein the pixel-level analysis comprises considering pixels of the two-dimensional representation for analysis if the pixels are at a predefined distance from each other creating a particular spatial relationship.

9. A method for extracting comprehensive data related to a dynamic component included in a two-dimensional representation of a design plan, the method comprising the steps of:
a. receiving, into a controller, the two-dimensional representation of the design plan;
b. representing at least one portion of the design plan as multiple dynamic components;
c. generating an interactive user interface comprising at least some of the multiple dynamic components representing the at least one portion of the design plan, each of the multiple dynamic components including a parameter changeable via the interactive user interface;
d. selecting, by a user, a segment of the at least one portion of the design plan on the interactive user interface;
e. analyzing, with an AI engine operative on the controller, the user-selected segment at pixel-level analysis and comparing with the multiple dynamic components representing the at least one portion of the design plan;
f. generating at least one match based on the comparison at step e, wherein the at least one match comprises at least one dynamic component, from the multiple dynamic components, matching with the user-selected segment;
g. providing a list of dynamic components matching with the user-selected segment;
h. extracting a comprehensive data related to the dynamic components matching with the user-selected segment; and
i. displaying on the interactive user interface the comprehensive data related to the dynamic components matching with the user-selected segment.

10. The method of claim 9, wherein the step of selecting the segment comprises marking on or around a desired segment of the at least one portion of the design plan on the interactive user interface.

11. The method of claim 9, wherein the step of selecting the segment comprises utilizing a polygon shape tool, accessible on the interactive user interface, and enabling the user to drag and position a polygon shape onto a desired segment.

12. The method of claim 11, wherein utilizing the polygon shape tool, accessible on the interactive user interface, comprises employing the polygon shape tool for the user to choose from a range of polygon shapes, provided by the AI engine within the interactive user interface for selection and placement.

13. The method of claim 9, wherein the pixel-level analysis comprises analyzing a polygon pixel pattern of the segment covered by a selected polygon shape.

14. The method of claim 9, wherein the pixel-level analysis comprises considering pixels of the two-dimensional representation for analysis if the pixels are at a predefined distance from each other, creating a particular spatial relationship.

15. The method of claim 9, wherein the comprehensive data comprises at least one of: name of the at least one dynamic component matching with the selected segment, type of the at least one dynamic component matching with the selected segment, number of the at least one dynamic component matching with the selected segment, and cost associated with the at least one dynamic component matching with the selected segment.

16. The method of claim 9, further comprising a step of displaying at least one automated suggestion related to the at least one dynamic component matching with the selected segment.

17. The method of claim 16, wherein the at least one automated suggestion comprises at least one of: a proposed design alteration, a dimension adjustment, a length and width suggestion, a material specification including recommended brands, a compliance adherence advice, and a safety enhancement advice.

18. The method of claim 9, wherein the selected segment comprises at least one of: a polygon shape, a door, a window, a stairwell, a wall, a floor, a ceiling, a ramp, a column, a beam, a roof, a skylight, a facade, and an HVAC component.

19. The method of claim 9, further comprising a step of displaying on the interactive user interface an advertisement comprising at least one of: a dynamic component from a particular brand, an alternative dynamic component from a different brand, a list of materials with pricing and purchase options, a contact information of a contractor available for hire, and a contact information of an architect available for hire.

20. The method of claim 19, wherein the dynamic component from the particular brand and the alternative dynamic component from the different brand align with one or both a required quality standard and a budget of the user.
